(19) United States
(12) Patent Application Publication
(10) Pub. No.: US 2010/0314757 A1
(43) Pub. Date: Dec. 16, 2010

(54) SEMICONDUCTOR DEVICE AND METHOD OF MANUFACTURING THE SAME

(75) Inventors: Michiaki SUGIYAMA, Kanagawa (JP); Takashi MIWA, Kanagawa (JP); Toshikazu ISHIKAWA, Kanagawa (JP)

Correspondence Address: MATTINGLY & MALUR, P.C., 1800 DIAGONAL ROAD, SUITE 370, ALEXANDRIA, VA, 22314, US

(73) Assignee: RENESAS ELECTRONICS CORPORATION, Kanagawa (JP)

(21) Appl. No.: 12/777,408

(22) Filed: May 11, 2010

(30) Foreign Application Priority Data
Jun. 11, 2009 (JP) 2009-139967

(51) Int. Cl. H01L 23/498; H01L 21/56

(52) U.S. Cl. 257/737; 438/124; 257/E21.502; 257/E23.068

(57) ABSTRACT

In a POP semiconductor device, a technology is provided which can increase the degree of freedom of semiconductor packages to be combined. A first metal conductive member is placed on a first wiring substrate which is a lower mounting substrate and a second metal conductive member is placed on a second wiring substrate which is an upper mounting substrate. By joining the corresponding portions of the first and second conductive members, the first and second wiring substrates are electrically coupled to each other. An electrode pad which is electrically coupled to the second conductive member and will have an upper semiconductor member 32 mounted thereon is formed on the main surface side of the second wiring substrate, and the electrode pad is also placed at a position planarly overlapping the lower semiconductor chip.

### CROSS-REFERENCE TO RELATED APPLICATION

The disclosure of Japanese Patent Application No. 2009-139967 filed on Jun. 11, 2009 including the specification, drawings and abstract is incorporated herein by reference in its entirety.

### BACKGROUND OF THE INVENTION

The present invention relates to a semiconductor device and technology of manufacturing the same, and particularly to a semiconductor device having a plurality of semiconductor chips and chip components mounted thereon and a technology useful for application to manufacturing the same.

For the purpose of downsizing motherboards having semiconductor packages or chip components (resistors, capacitors, or inductors) mounted thereon, or speeding up semiconductor systems, there have been developed MCM (Multi Chip Module) semiconductor devices having various types of semiconductor chips (microcomputer chip, memory chip, etc.) and chip components mounted on a single semiconductor device.

As such an MCM semiconductor device, there is a POP (Package On Package) semiconductor device configuration, such as that shown in Japanese Patent Laid-Open No. 2007-123454 (patent document 1), in which a plurality of wiring substrates having semiconductor chips or chip components mounted thereon is prepared, with one wiring substrate laminated on another.

In addition, there is another configuration of a POP semiconductor device such as that disclosed in Japanese Patent Laid-Open No. 2008-288490 (patent document 2) shown in FIG. 2(D), in which a lower wiring substrate (first substrate 10) and an upper wiring substrate (second substrate 20) are electrically coupled via a ball-shaped electrode, with another semiconductor package mounted on the upper wiring substrate.

Furthermore, there is another configuration of a POP semiconductor device such as that disclosed in Japanese Patent Laid-Open No. 2008-300498 (patent document 3) shown in FIG. 10(h), in which a lower wiring substrate (first wiring layer 101) and an upper wiring substrate (second wiring layer 104) respectively have electrodes (bump 118) formed thereon to be subsequently joined together.

The POP semiconductor device is considered to be useful as a configuration of MCM semiconductor devices because yield of semiconductor devices can be increased by preparing semiconductor packages preliminarily selected as non-defective items and combining these semiconductor packages according to the desired function.

When manufacturing a POP semiconductor device, therefore, the inventors of the present invention first examined the configuration disclosed in the patent document 1.

As a result, it has been revealed in the configuration disclosed in the patent document 1 that the location of an external terminal formed on the wiring substrate placed at the upper position for electrically coupling with the lower wiring substrate may be restricted, because semiconductor chips or chip components are mounted on the wiring substrate placed at the lower position.

Therefore, the inventors of the present invention examined the configuration disclosed in the patent document 2.

In the case of the configuration disclosed in the patent document 2, the location of placing the external terminal of the laminated semiconductor package (electronic component 52) need not be aligned with the position of the electrode pad formed on the lower wiring substrate (first substrate 10), because another wiring substrate (second substrate 20) is laminated on the lower wiring substrate (first substrate 10), and another semiconductor package (electronic component 52) is mounted over this wiring substrate (second substrate 20). In other words, the location of placing the external terminal is not restricted.

In the configuration disclosed in the patent document 2, however, the lower wiring substrate (first substrate 10) and the upper wiring substrate (second substrate 20) are electrically coupled via the ball-shaped electrode. Therefore, the height (size) of the electrode must be higher than the height of the semiconductor chips or chip components mounted over the lower wiring substrate. Accordingly, the pitch between adjacent electrodes becomes large, making it difficult to downsize the external dimension of the wiring substrate.

Therefore the inventors of the present invention examined the configuration disclosed in the patent document 3.

With the configuration disclosed in the patent document 3, the size (horizontal width) of each electrode can be reduced because of a structure such that electrodes having an Au plating film (bump 118) formed thereon are placed and joined together on the lower wiring substrate (first wiring layer 101) and the upper wiring substrate (second wiring layer 104).

The manufacturing method disclosed in the patent document 3, however, prepares an adhesive layer having a gap (second gap 135) formed therein, with the adhesive layer being provided between the lower and the upper wiring substrates so that the electrode is located within this gap, and the joint of the electrodes is covered with the adhesive layer by applying heat and pressure thereto.

In recent years, the number of electrodes that are electrically coupled to semiconductor chips has been increasing along with enhancement of functionality of semiconductor devices. Therefore, a high alignment precision is required when forming a gap corresponding to a plurality of electrodes on the adhesive layer and when placing the electrodes within a plurality of gaps respectively. In addition, although the patent document 3 explains that gaps corresponding to respective electrodes need not be formed, there is an adhesive layer intervening between the lower electrode and the upper electrode in this case, and whereby resistance component that occurs in the conduction path between the lower semiconductor package and the upper semiconductor package becomes high. Accordingly, it becomes difficult to cope with an increase in the operation speed of the semiconductor device.

It is an object of the present invention to provide a technology that can increase the degree of freedom of semiconductor packages to be combined in an MCM semiconductor device.

It is another object of the present invention to provide a technology that can realize downsizing of an MCM semiconductor device.

It is another object of the present invention to provide a technology that can improve reliability of an MCM semiconductor device.

It is another object of the present invention to provide a technology that can increase the operation speed of an MCM semiconductor device.

The other purposes and the new feature of the present invention will become clear from the description of the present specification and the accompanying drawings.

### SUMMARY OF THE INVENTION

The following explains briefly the outline of a typical invention among the inventions disclosed in the present application.

(1) The method of manufacturing a semiconductor device according to the present invention includes the following steps of: (a) providing a first substrate having a first main surface, a first electrode pad formed on the first main surface, a second electrode pad placed closer to the periphery of the first main surface than the first electrode pad, a first conductive member formed on the second electrode pad, a conductive film formed on the surface of the first conductive member, a first back surface opposite to the first main surface, and a third electrode pad formed on the first back surface; (b) mounting a semiconductor chip having a front surface, a bonding pad formed on the front surface, and a back surface opposite to the front surface on the first main surface of the first substrate; (c) electrically coupling the bonding pad of the semiconductor chip and the first electrode pad of the first substrate via a second conductive member; (d) disposing a second substrate having a second main surface, a fourth electrode pad formed on the second main surface, a second back surface opposite to the second main surface, a fifth electrode pad formed on the second back surface, and a third conductive member formed on the fifth electrode pad on the first substrate such that the second back surface of the second substrate faces the first main surface of the first substrate; (e) after the step (d), electrically coupling the third conductive member to the first conductive member via the conductive film; (f) after the step (e), supplying resin between the first substrate and the second substrate to seal the semiconductor chip and the joint of the first conductive member and the third conductive member; and (g) after the step (f), forming an external terminal at the third electrode pad of the first substrate.

(2) In addition, a semiconductor device according to the present invention includes: a first substrate having a first main surface, a first electrode pad formed on the first main surface, a second electrode pad placed closer to the periphery of the first main surface than the first electrode pad, a first conductive member formed on the second electrode pad, a first back surface opposite to the first main surface, and a third electrode pad formed on the first back surface; a semiconductor chip having a front surface, a bonding pad formed on the front surface, and a back surface opposite to the front surface, and mounted on the first main surface of the first substrate; a second conductive member electrically coupling the bonding pad of the semiconductor chip and the first electrode pad of the first substrate; a second substrate having a second main surface, a fourth electrode pad formed on the second main surface, a second back surface opposite to the second main surface, a fifth electrode pad formed on the second back surface, and a third conductive member formed on the fifth electrode pad, and disposed on the first substrate such that the second back surface faces the first main surface of the first substrate; a conductive film electrically coupling the first conductive member and the third conductive member; resin formed between the first substrate and the second substrate so as to seal the semiconductor chip and the joint of the first conductive member and the third conductive member; and an external terminal formed on the third electrode pad of the first substrate, wherein the resin is formed between the semiconductor chip and the second back surface of the second substrate.

The following explains briefly the effect acquired by the typical invention among the inventions disclosed in the present application.

(1) Degree of freedom of semiconductor packages to be combined in an MCM semiconductor device can be increased.

(2) Downsizing of MCM semiconductor devices can be realized.

(3) Reliability of MCM semiconductor devices can be improved.

(4) Operation speed of MCM semiconductor devices can be increased.

### BRIEF DESCRIPTION OF THE DRAWINGS

FIG. 1 is a plan view illustrating the main surface side of a motherboard to be a base substrate of forming a semiconductor device according to an embodiment of the present invention;

FIG. 2 is a plan view illustrating the back surface side of the motherboard to be the base substrate of forming the semiconductor device according to an embodiment of the present invention;

FIG. 3 is a plan view illustrating the main surface side of a motherboard to be a sub-substrate of forming the semiconductor device according to an embodiment of the present invention;

FIG. 4 is a plan view illustrating the back surface side of the motherboard to be the sub-substrate of forming the semiconductor device according to an embodiment of the present invention;

FIG. 5 is a cross-sectional view illustrating the main parts of a manufacturing method of the motherboard shown in FIGS. 1 to 4;

FIG. 6 is a cross-sectional view illustrating the main parts in a manufacturing process of the motherboard, following FIG. 5;

FIG. 7 is a cross-sectional view illustrating the main parts in the manufacturing process of the motherboard, following FIG. 6;

FIG. 8 is a cross-sectional view illustrating the main parts in the manufacturing process of the motherboard, following FIG. 7;

FIG. 9 is a cross-sectional view illustrating the main parts in the manufacturing process of the motherboard, following FIG. 8;

FIG. 10 is a cross-sectional view illustrating the main parts in the manufacturing process of the motherboard, following FIG. 9;

FIG. 11 is a cross-sectional view illustrating the main parts in the manufacturing process of the motherboard, following FIG. 10;

FIG. 12 is a cross-sectional view illustrating the main parts in the manufacturing process of the motherboard, following FIG. 11;

FIG. 13 is a cross-sectional view illustrating the main parts in the manufacturing process of the motherboard, following FIG. 12;

FIG. 14 is a cross-sectional view illustrating the main parts in the manufacturing process of the motherboard, following FIG. 13;

FIG. 15 is a cross-sectional view illustrating the main parts in the manufacturing process of the motherboard, following FIG. 14;

FIG. 16 is a cross-sectional view illustrating the main parts in the manufacturing process of the motherboard, following FIG. 15;

FIG. 17 is a cross-sectional view illustrating the main parts in the manufacturing process of the motherboard, following FIG. 16;

FIG. 18 is a cross-sectional view illustrating the main parts in the manufacturing process of the motherboard, following FIG. 17;

FIG. 19 is a cross-sectional view illustrating the main parts in the manufacturing process of the motherboard, following FIG. 18;

FIG. 20 is a cross-sectional view illustrating the main parts in the manufacturing process of the motherboard, following FIG. 19;

FIG. 21 is a cross-sectional view illustrating the main parts in the manufacturing process of the motherboard, following FIG. 20;

FIG. 22 is a cross-sectional view illustrating the main parts in the manufacturing process of the motherboard, following FIG. 21;

FIG. 23 is a cross-sectional view illustrating the main parts in the manufacturing process of the motherboard, following FIG. 22;

FIG. 24 is a cross-sectional view illustrating the main parts in the manufacturing process of the motherboard, following FIG. 23;

FIG. 25 is a cross-sectional view illustrating the main parts in the manufacturing process of the motherboard, following FIG. 24;

FIG. 26 is a cross-sectional view illustrating the main parts of the manufacturing process of the motherboard shown in FIGS. 1 to 4;

FIG. 27 is a cross-sectional view illustrating the main parts in the manufacturing process of the motherboard, following FIG. 26;

FIG. 28 is a cross-sectional view illustrating the main parts in the manufacturing process of the motherboard, following FIG. 27;

FIG. 29 is a cross-sectional view illustrating the main parts in the manufacturing process of the motherboard, following FIG. 28;

FIG. 30 is a cross-sectional view illustrating the main parts in the manufacturing process of the motherboard, following FIG. 29;

FIG. 31 is a cross-sectional view illustrating the main parts in the manufacturing process of the motherboard, following FIG. 30;

FIG. 32 is a cross-sectional view illustrating the main parts in the manufacturing process of the motherboard, following FIG. 31;

FIG. 33 is a cross-sectional view illustrating the main parts in the manufacturing process of the motherboard, following FIG. 32;

FIG. 34 is a cross-sectional view illustrating the main parts of the manufacturing method of the semiconductor device according to an embodiment of the present invention;

FIG. 35 is a cross-sectional view illustrating the main parts in the manufacturing process of the semiconductor device, following FIG. 34;

FIG. 36 is a plan view illustrating the main parts in the manufacturing process of the semiconductor device according to an embodiment of the present invention;

FIG. 37 is a cross-sectional view illustrating the main parts in the manufacturing process of the semiconductor device according to an embodiment of the present invention;

FIG. 38 is a cross-sectional view illustrating the main parts in the manufacturing process of the semiconductor device, following FIG. 35;

FIG. 39 is a cross-sectional view illustrating the main parts in the manufacturing process of the semiconductor device according to an embodiment of the present invention;

FIG. 40 is a cross-sectional view illustrating the main parts in the manufacturing process of the semiconductor device, following FIG. 39;

FIG. 41 is a cross-sectional view illustrating the main parts in the manufacturing process of the semiconductor device, following FIG. 40;

FIG. 42 is a cross-sectional view illustrating the main parts in the manufacturing process of the semiconductor device, following FIG. 41;

FIG. 43 is a cross-sectional view illustrating the main parts in the manufacturing process of the semiconductor device, following FIG. 42;

FIG. 44 is a cross-sectional view illustrating the main parts in the manufacturing process of the semiconductor device, following FIG. 43;

FIG. 45 is a cross-sectional view illustrating the main parts in the manufacturing process of the semiconductor device according to an embodiment of the present invention;

FIG. 46 is a plan view in the manufacturing process of the semiconductor device according to an embodiment of the present invention;

FIG. 47 is a cross-sectional view illustrating the main parts in the manufacturing process of the semiconductor device, following FIG. 45;

FIG. 48 is a plan view in the manufacturing process of the semiconductor device, following FIG. 46;

FIG. 49 is a cross-sectional view illustrating the main parts of the semiconductor device according to an embodiment of the present invention;

FIG. 50 is a system block diagram when the semiconductor device according to an embodiment of the present invention is mounted on an externally installed substrate;

FIG. 51 is a plan view illustrating the main parts of the semiconductor device according to an embodiment of the present invention;

FIG. 52 is a plan view illustrating the main parts of the semiconductor device according to an embodiment of the present invention;

FIG. 53 is a cross-sectional view illustrating the main parts of the semiconductor device according to an embodiment of the present invention;

FIG. 54 is a plan view of the upper surface side of a semiconductor chip included in the semiconductor device according to an embodiment of the present invention;

FIG. 55 is a plan view of the lower surface side of the semiconductor chip included in the semiconductor device according to an embodiment of the present invention; and

FIG. 56 is a cross-sectional view taken along line A-A of FIG. 54.

### DETAILED DESCRIPTION OF THE PREFERRED EMBODIMENTS

### [1] Explanation of Notations, Basic Terms, and Terminology in the Present Application

The following embodiments will be explained, divided into plural sections or embodiments, if necessary for convenience. Except for the case where it shows clearly in particular, they are not mutually unrelated and one has relationships such as a modification, details, and supplementary explanation of some or entire of another.

In the following embodiments, when referring to the number of elements, etc. (including the number, a numeric value, an amount, a range, etc.), they may be not restricted to the specific number but may be greater or smaller than the specific number, except for the case where they are clearly specified in particular and where they are clearly restricted to a specific number theoretically.

Furthermore, in the following embodiments, it is needless to say that an element (including an element step etc.) is not necessarily indispensable, except for the case where it is clearly specified in particular and where it is considered to be clearly indispensable from a theoretical point of view, etc. Additionally, with regard to components in the embodiments, it is needless to say that expressions such as “comprising A” or “comprises A” do not exclude other elements unless it is explicitly stated that only the component is included.

Similarly, in the following embodiments, when shape, position relationship, etc. of an element etc. is referred to, what resembles or is similar to the shape substantially shall be included, except for the case where it is clearly specified in particular and where it is considered to be clearly not right from a theoretical point of view. This statement also applies to the numeric value and range described above.

Additionally, when referring to materials or the like, specified materials are main materials where subsidiary elements, additives, additional elements are not excluded unless explicitly stated otherwise or when that is not the case circumstantially or in principle. For example, it is assumed that a silicon member includes not only pure silicon but also binary or ternary alloys (e.g., SiGe) having additive impurities and silicon as main elements, unless explicitly stated otherwise.

Additionally, in all the drawings illustrating the embodiments, components having identical functions are provided with identical reference numerals as a general rule, for which duplicate description are omitted.

Additionally, in the drawings used for the embodiments, plan views may be partially hatched for ease of viewing.

### [2] Explanation of a Semiconductor Device

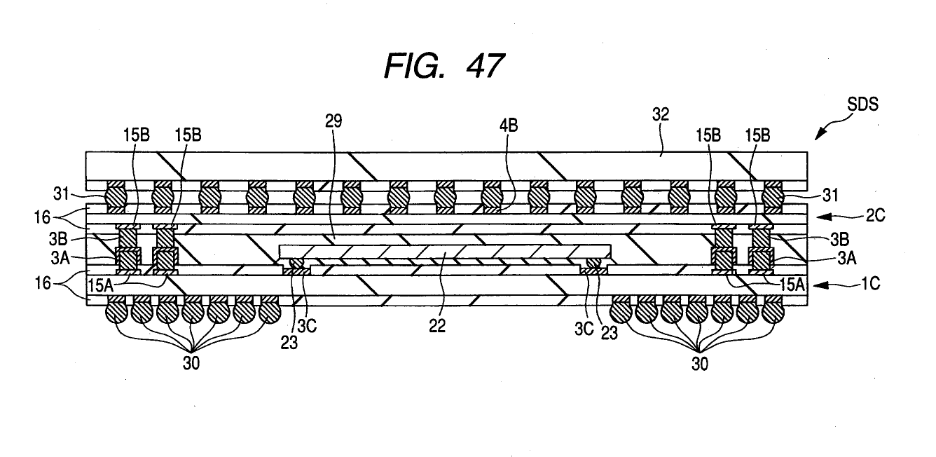

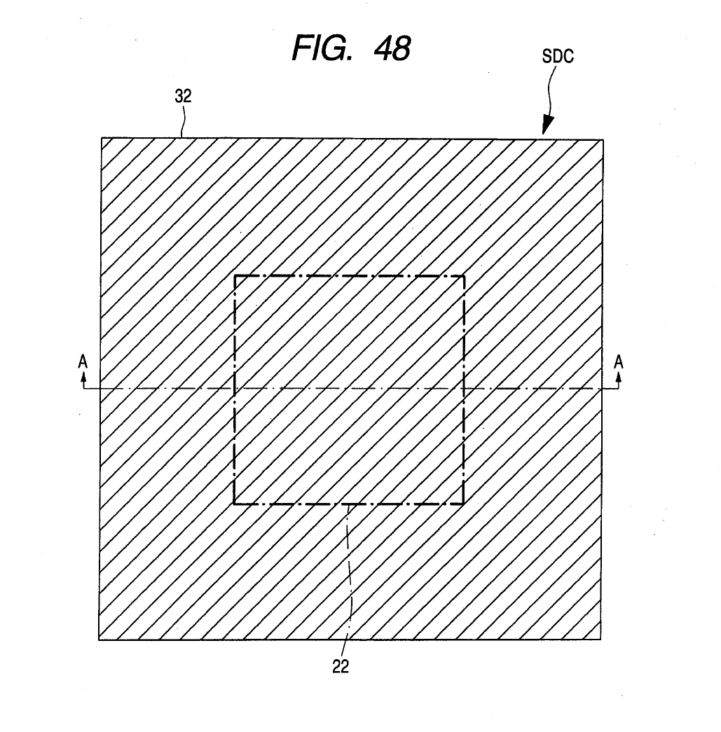

FIG. 48 is a top plan view of a completed semiconductor device (semiconductor system) SDS, and FIG. 47 is a cross-sectional view taken along line A-A of FIG. 48.

In a configuration of the semiconductor device of a representative embodiment of the present invention, a semiconductor chip (chip) 22 is mounted over a base wiring substrate (base substrate, interposer) 1C, as shown in FIG. 47. In addition, an auxiliary wiring substrate (sub-substrate, interposer) 2C is placed over the wiring substrate 1C so as to cover the semiconductor chip 22. Additionally, the wiring substrate 2C located on the upper side is electrically coupled to the lower wiring substrate 1C via a conductive member 3B formed on the lower surface (back surface) of the wiring substrate 2C and a conductive member 3A formed on the upper surface (main surface, surface) of the wiring substrate 1C. In addition, mold resin (sealing body) 29 is formed between the lower wiring substrate 1C and the upper wiring substrate 2C so as to seal the semiconductor chip 22. In addition, a plurality of bump electrodes to be external terminals is formed on the lower surface (back surface, mounting surface) of the lower wiring substrate 1C. Furthermore, a semiconductor member 32 such as a semiconductor chip which has been separately prepared, a semiconductor package having a semiconductor chip mounted thereon, or a chip component is mounted over the upper wiring substrate 2C. A part of the mold resin (sealing body) 29 is also formed between the semiconductor chip 22 and the upper wiring substrate 2C. Therefore, the problem that the wiring substrate 2C bends when mounting the semiconductor member 32 due to its load even if the thickness of the wiring substrate 2C is thinned can be avoided. In addition, a variety of semiconductor systems can be built by changing the type of the semiconductor member 32 mounted over the wiring substrate 2C.

### [3] Explanation of Base Substrate

Next, the wiring substrate 1C in this embodiment will be described in more detail.

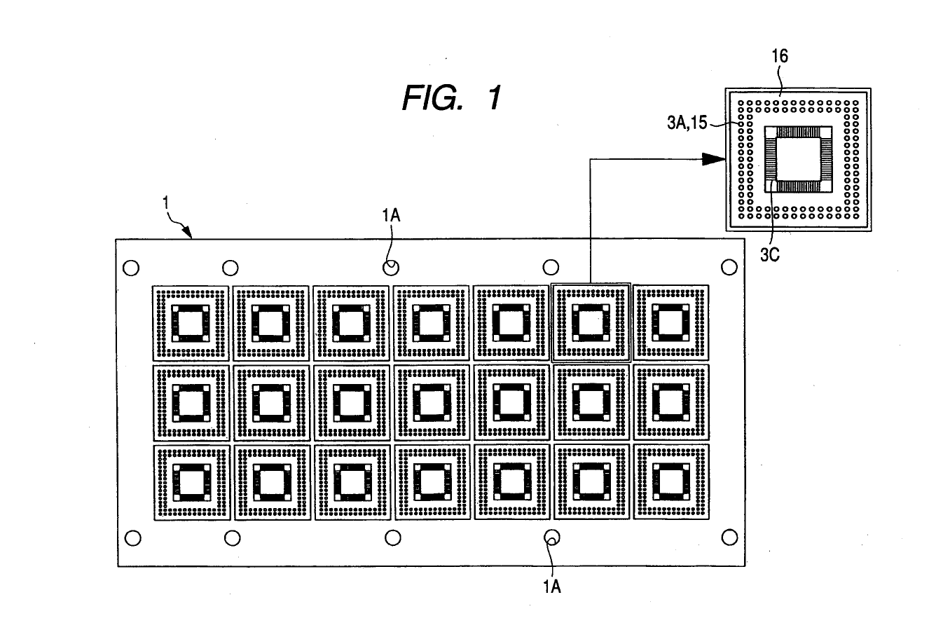

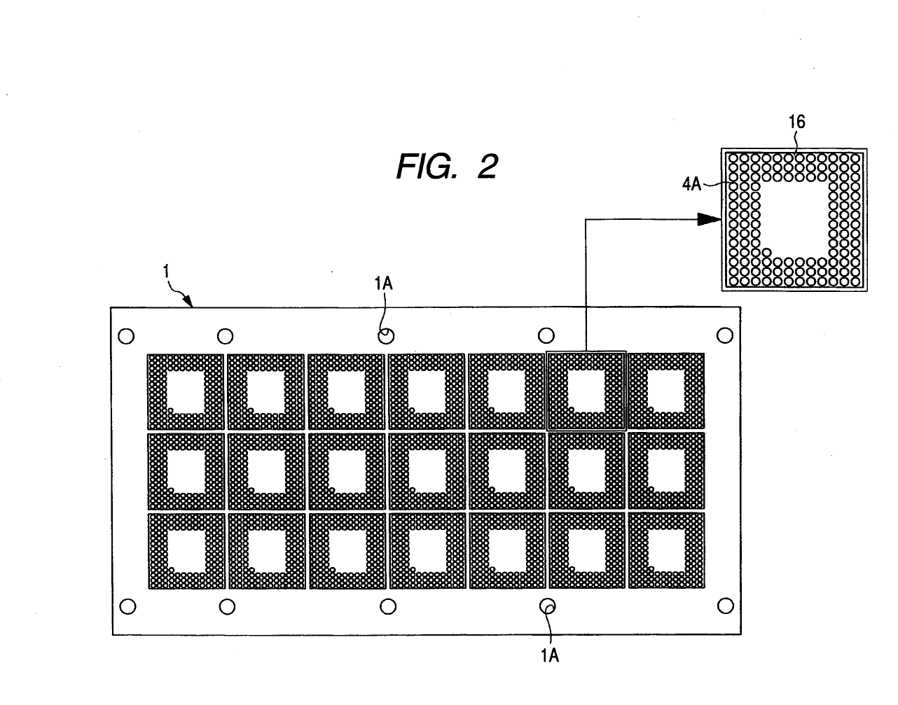

FIG. 1 is a plan view of the upper surface (main surface, surface) of a multi-piece substrate having a plurality of base wiring substrates (package regions) 1C (see FIGS. 45 to 47) formed thereon, and FIG. 2 is a plan view of the lower surface (back surface, mounting surface) of the multi-piece substrate shown in FIG. 1.

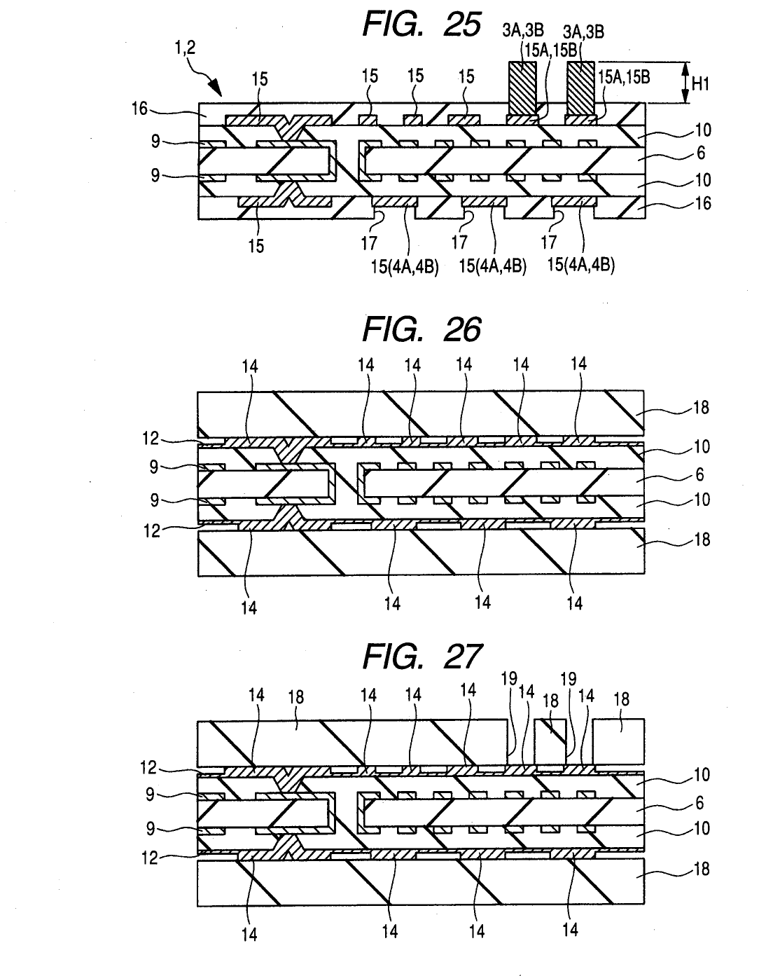

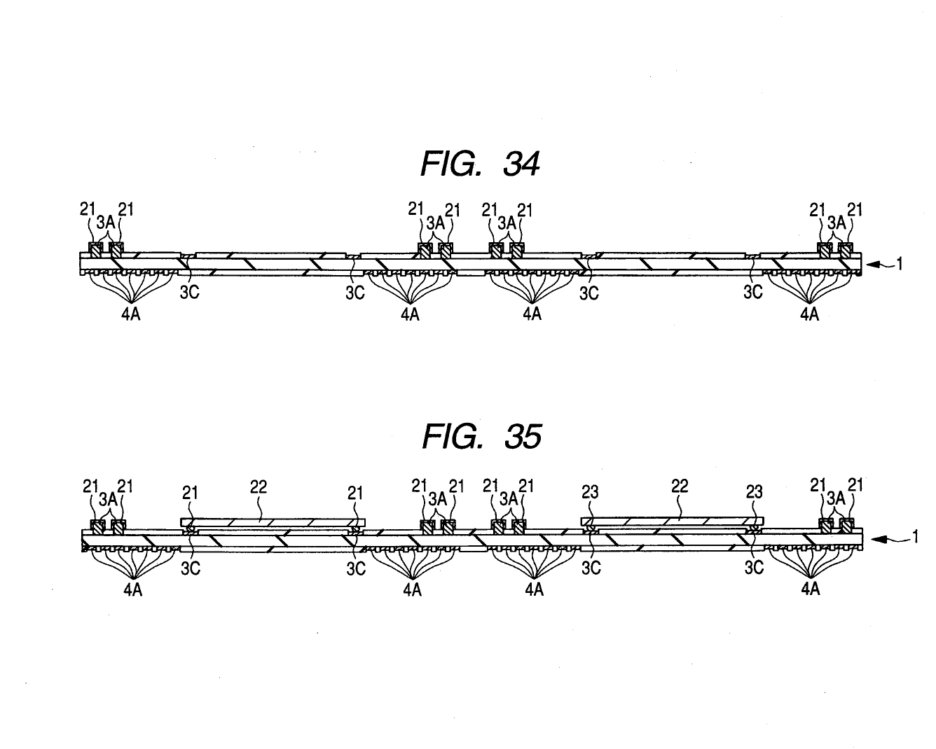

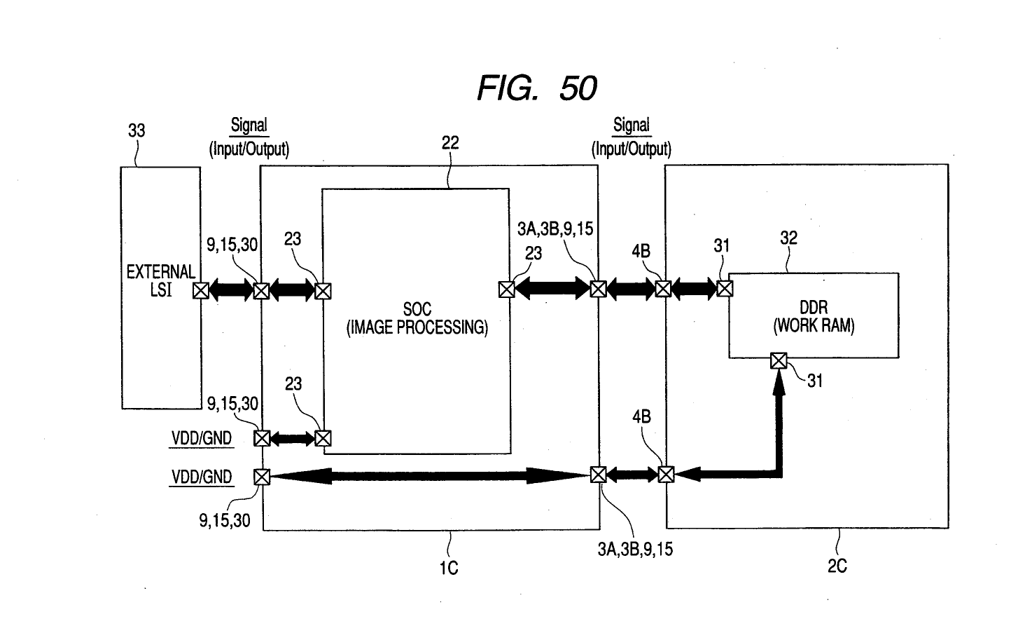

The planar shape of the base wiring substrate 1C, which is one piece of the multi-piece substrate, is rectangular, as shown in FIG. 1, which is quadrangular in this embodiment. The material of the wiring substrate 1C includes so-called glass epoxy resin, which is resin impregnated in glass fiber, for example. As shown in FIG. 1, an electrode pad (bonding lead) 3C electrically coupled to the semiconductor chip 22, which will be subsequently mounted thereon, is formed in the central part of the upper surface (surface) of the wiring substrate 1C. A plurality of electrode pads 3C is formed along each side of the wiring substrate 1C. In addition, a plurality of electrode pads (lands) 15A is formed around these electrode pads 3C, in other words, closer to the periphery of the wiring substrate 1C than the electrode pads 3C, as shown in FIG. 45. The electrode pads 15A are formed across a plurality of rows along each side of the wiring substrate 1C, and electrically coupled to the electrode pads 3C respectively, as shown in the system block diagram of FIG. 50. Additionally, a solder resist (insulating film, main surface insulating film) 16 (see FIGS. 25 and 33) is formed on the upper surface of the wiring substrate 1C to expose a part (surface) of the electrode pads 15A and 3C, respectively. In addition, a conductive member 3A is formed on the surface of the electrode pad 15A exposed from the solder resist 16, as shown in FIG. 34. In this embodiment, the conductive member 3A is formed in the shape of a post (pillar), and made of copper (Cu), for example. Furthermore, a metal film (conductive film) 21 is formed on the surface of the conductive member 3A, as shown in FIG. 37. The method of forming the conductive member 3A will be described below. The material of the metal film 21 is solder (including lead-free solder). In this occasion, the melting point of the solder composing the metal film 21 is higher than that of the bump electrode (solder ball) 30 to be formed in the lower surface of the wiring substrate 1C in a subsequent process. Fracture of the joint between the conductive members 3A and 3B can thus be avoided in the process of forming the bump electrode 30.

On the lower surface (mounting surface) of the wiring substrate 1C, a plurality of electrode pads (lands) 4A is formed as shown in FIG. 2. In addition, the electrode pads 4A are formed along each side of the wiring substrate 1C across a plurality of rows, and electrically coupled to the electrode pads 3C, respectively, as shown in the system block diagram of FIG. 50. Furthermore, a solder resist (insulating film, back surface insulating film) 16 is formed on the lower surface of the wiring substrate 1C to expose a part (surface) of the electrode pads 4A.

In addition, the wiring substrate 1C has a plurality (four in this embodiment) of wiring layers, although not shown. Each of the electrode pad (bonding lead) 3C and the electrode pad (land) 15A includes a part of wirings (wiring pattern) formed on the first level (top level) wiring layer, whereas the electrode pad (land) 4A includes a part of wirings (wiring pattern) formed on the fourth level (bottom level) wiring layer.

### [4] Explanation of the Sub-Substrate

Next, the wiring substrate 2C in this embodiment will be described in detail.

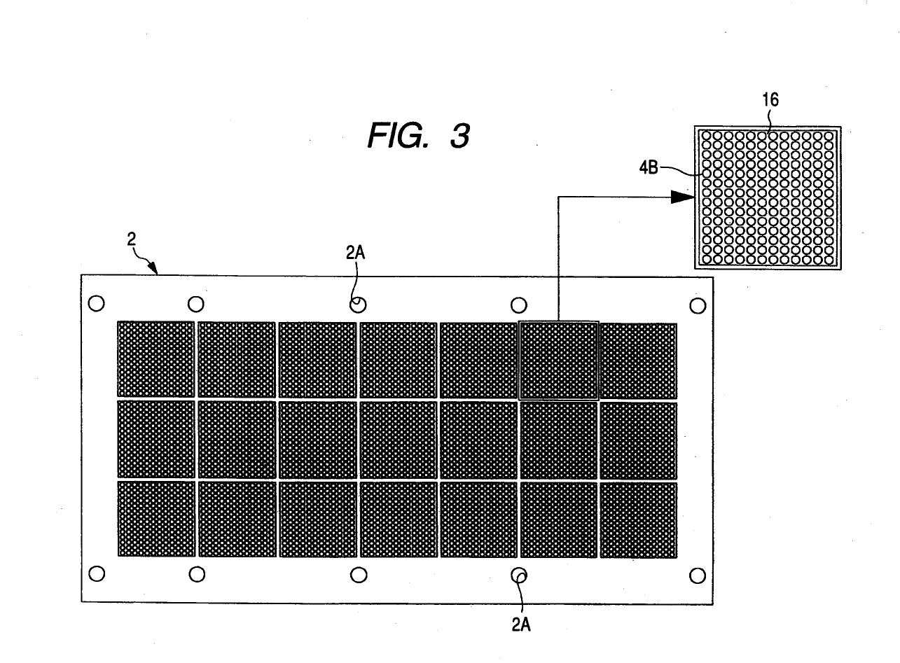

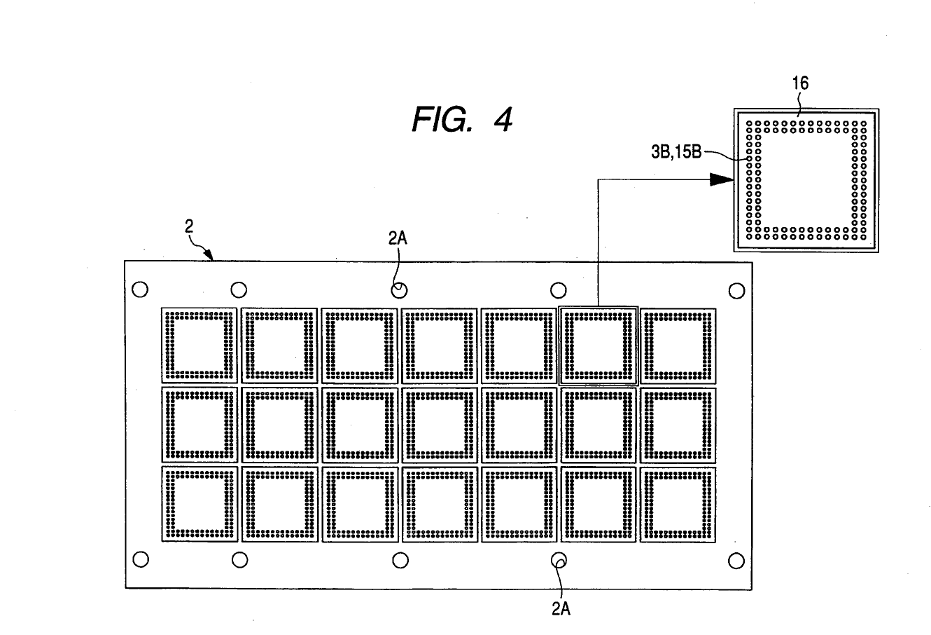

FIG. 3 is a plan view of the upper surface (main surface, surface) side of a multi-piece substrate on which a plurality of wiring substrates (package regions) 2C to be sub-substrates (see FIGS. 45 to 47) is formed, and FIG. 4 is a plan view of the lower surface (back surface, mounting surface) side of the multi-piece substrate shown in FIG. 3.

The planar shape of one piece of the wiring substrate 2C is rectangular, as shown in FIG. 3, which is quadrangular in this embodiment. The material of the wiring substrate 2C includes so-called glass epoxy resin having resin impregnated into glass fiber, for example. Additionally, a plurality of electrode pads (lands, bonding leads) 4B is formed on the upper surface (surface) of the wiring substrate 2C. The electrode pads 4B are also, formed, as shown in FIG. 45, in a region planarly overlapping the semiconductor chip 22 which will be subsequently mounted on the lower wiring substrate 1C. Additionally, a solder resist (insulating film, main surface insulating film) 16 is formed on the upper surface of the wiring substrate 2C so as to expose a part (surface) of the electrode pads 4B. Therefore, it becomes possible in subsequent processes to mount, over the semiconductor chip 22, a semiconductor member (semiconductor chip, semiconductor package, or chip component) having an external size different from that of the base wiring substrate 1C, or a semiconductor member having an external terminal formed in a region planarly overlapping the semiconductor chip 22, by providing the auxiliary wiring substrate 2C over the base wiring substrate 1C having the semiconductor chip 22 mounted thereon.

On the lower surface (mounting surface) of the wiring substrate 2C, a plurality of electrode pads (lands) 15B is formed, as shown in FIG. 45. The electrode pads 15B are electrically coupled, respectively, to the electrode pads 4B formed on the upper surface of the wiring substrate 2C. In addition, the electrode pads 15B are formed along each side of the wiring substrate 2C across a plurality of rows in the lower surface of the wiring substrate 2C, as shown in FIG. 4. Each of these electrode pads 15B is placed at the same position (a planarly overlapping position when the wiring substrate 2C is laminated over the wiring substrate 1C) as each of the electrode pads 15A formed on the upper surface of the base wiring substrate 1C. Additionally, a solder resist (insulating film, back surface insulating film) 16 (see FIGS. 25 and 33) is formed on the lower surface of the wiring substrate 2C so as to expose a part (surface) of each of the electrode pads 15B. Furthermore, a conductive member 3B is formed on the surface of electrode pad 15B exposed from the solder resist 16, as shown in FIG. 39. In this embodiment, the conductive member 3B is formed in the shape of a post (pillar), and made of copper (Cu), for example. The method of forming the conductive member 3B will be described below.

Although not shown, the wiring substrate 2C has a plurality (two in this embodiment) of wiring layers. The electrode pad (land) 4B includes a part of wiring (wiring pattern) formed in the first level (top level) wiring layer, whereas the electrode pad (land) 15B includes apart of wiring (wiring pattern) formed in the second level (bottom level) wiring layer. In this embodiment, as shown in the system block diagram of FIG. 50, the semiconductor chip 22 mounted on the wiring substrate 1C controls the semiconductor member 32 mounted on the wiring substrate 2C based on the signal from an external LSI 33. In addition, the power source potential and the reference potential required for operating, the semiconductor member 32 are also supplied to the semiconductor member 32 from the external LSI 33 via the wiring substrate 1C. In this embodiment, therefore, the wiring substrate 1C having a larger number of wiring layers than that of the wiring substrate 2C is used.

### [5] Explanation of Semiconductor Chip

Next, the semiconductor chip 22 mounted over the wiring substrate 1C will be described in detail.

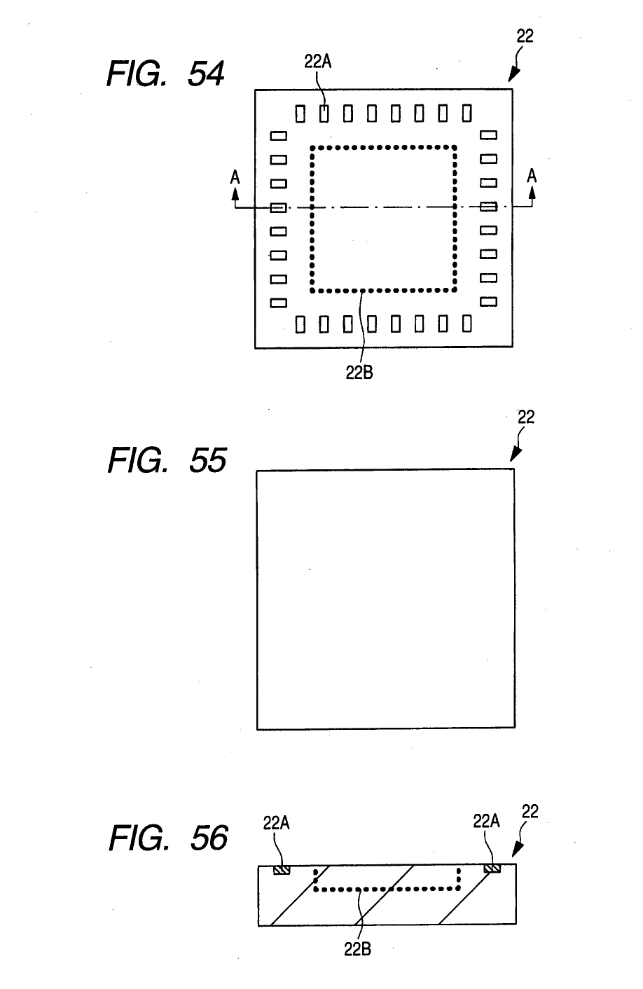

FIG. 54 is a plan view of the upper surface (surface, main surface) side of the semiconductor chip 22 mounted over the wiring substrate 1C, FIG. 55 is a plan view of the lower surface (back surface) side opposite to the upper surface shown in FIG. 54, and FIG. 56 is a cross-sectional view taken along the line A-A of FIG. 54.

The planar shape of the semiconductor chip 22 is rectangular, as shown in FIG. 54, which is quadrangular in this embodiment. The material of the semiconductor chip 22 includes silicon (Si), for example. A plurality of electrode pads 22A is formed along each side of the semiconductor chip 22 on the upper surface (main surface) of the semiconductor chip 22. In addition, a circuit element (semiconductor element) 22B is formed in the central part of the semiconductor chip 22 and, although not shown, the electrode pads 22A formed in the periphery of the circuit element 22B are electrically coupled to the circuit element 22B via the wiring formed in the semiconductor chip 22. The circuit element is formed on the upper surface side of the semiconductor chip 22, as shown in FIG. 56. The semiconductor chip 22 in this embodiment is a controller-based semiconductor chip, and the circuit element 22B includes, as shown in FIG. 50, an external interface that inputs and outputs signals between the circuit element 22B and the external LSI 33 provided outside the completed semiconductor device (semiconductor system) SDS, and an internal interface that inputs and outputs signals between the circuit element 22B and the semiconductor member 32 provided inside the semiconductor device.

The planar shape of the lower surface (back surface) opposite to the upper surface of the semiconductor chip 22 is rectangular as shown in FIG. 55, which is quadrangular in this embodiment, similar to the upper surface side.

### [6] Method of Manufacturing a Semiconductor Device

### Semiconductor System

Next, the method of manufacturing the semiconductor device (semiconductor system) SDS of this embodiment will be described below. As previously described, the semiconductor device of this embodiment is a POP (Package On Package) semiconductor device, which is a type of MCM. In addition, FIGS. 1 to 4 are plan views of the wiring substrate used for manufacturing the POP semiconductor device, where FIGS. 1 and 2 are respectively plan views of the main surface side and the back surface side of the motherboard 1 to be the lower wiring substrate, and FIGS. 3 and 4 are respectively plan views of the main surface side and the back surface side of the motherboard 2 to be the upper wiring substrate laminated on the wiring substrate 1C. In addition, FIGS. 1 to 4 show, in enlarged views, the main surface side or the back surface side of the region to be a base substrate or a sub-substrate.

The motherboards 1 and 2 shown in FIGS. 1 to 4 are MAP (Mold Array Package) motherboards, in which a plurality of regions to be the wiring substrates 1C or the wiring substrates 2C is arranged such that a plurality of wiring substrates 1C or wiring substrates 2C can be obtained from a single motherboard 1 or 2. The motherboards 1 and 2 respectively have a plurality of guide holes 1A and guide holes 2A formed therein, in which a region to be the wiring substrate 1C and a region to be the wiring substrate 2C face to each other at the corresponding portions such that the main surface of the motherboard 1 and the back surface of the motherboard 2 face to each other and a guide is inserted so as to pass through corresponding guide holes 1A and 2A, as will be described in detail below.

A plurality of post-shaped (pillar-shaped) conductive members 3A is formed on the main surface side of the motherboard 1 (region to be each wiring substrate 1C), and a plurality of metal conductive members 3B is formed on the back surface side of the motherboard 2 (region to be each wiring substrate 2C). These conductive members 3A and conductive members 3B are respectively positioned in a one to one correspondence when a region to be the corresponding wiring substrate 1C and a region to be the corresponding wiring substrate 2C are planarly overlapped. By joining the conductive members 3A and 3B with the corresponding ones, the wiring substrate 1C and the wiring substrate 2C are electrically coupled, details of which will be described along with explanation of the manufacturing process of the semiconductor device of this embodiment. In addition, an electrode pad (bonding lead) 3C for mounting the semiconductor chip is formed on the main surface side of the motherboard 1.

An electrode pad 4A for electrically coupling the semiconductor device of this embodiment to the outside is formed on the back surface of the motherboard 1, and an electrode pad 4B for mounting semiconductor chips or chip components is formed on the main surface of the motherboard 2. In addition, wiring layers are formed in each of the regions to be the wiring substrates 1C and regions to be the wiring substrates 2C in the motherboards 1 and 2, the wiring layers electrically coupling the conductive member 3A and the electrode pad 4A, and electrically coupling the conductive member 3B and the electrode pad 4B.

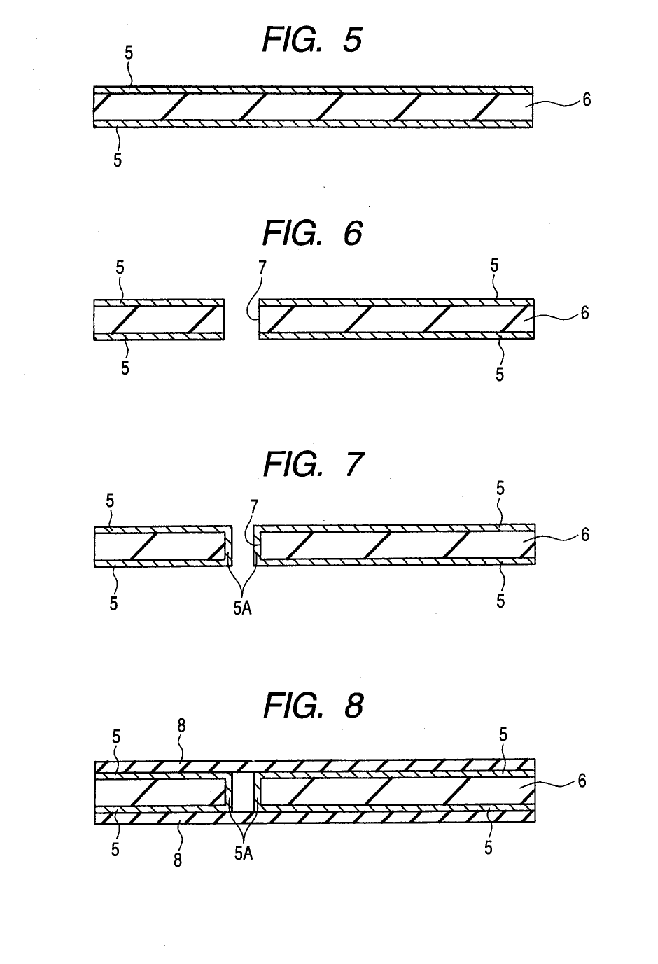

Next, the manufacturing process of the motherboards 1 and 2 will be described referring to FIGS. 5 to 33. FIGS. 5 to 33 are cross-sectional views of the main parts in the manufacturing process of the motherboards 1 and 2. Here, although the motherboards 1 and 2 have an approximately similar structure except for the numbers of internal wiring layers, their main surface and back surface are reversed such that the side with the conductive member 3A placed thereon is the main surface of the motherboard 1 whereas the side with the post 3 placed thereon is the back surface of the motherboard 2 in this embodiment, as described before. For ease of understanding, therefore, it is assumed that the main surface and the back surface of the motherboard 1 is mentioned when referring to the main surface and the back surface in the description of the manufacturing process of the motherboards 1 and 2.

First, insulating core material 6 is prepared having a thin copper film 5 formed on both the main and the back surfaces thereof (see FIG. 5). Glass epoxy resin, BT resin, aramid nonwoven fabric, or the like may be exemplified as the material.

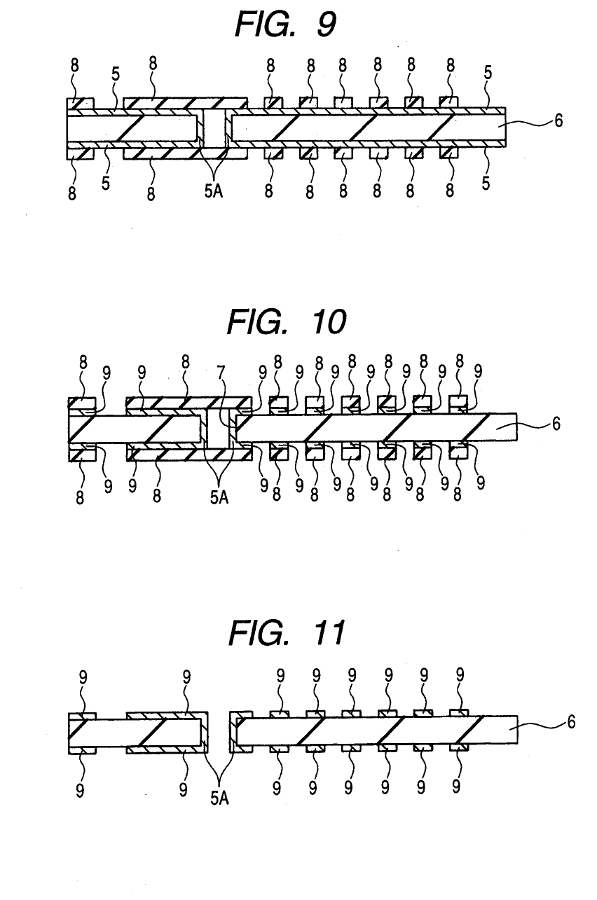

Next, a through-hole 7 penetrating through the main surface and the back surface of the core material 6 is formed by drilling or laser processing (see FIG. 6). Subsequently, a copper film 5A is formed on a wall surface of the through-hole 7 by plating, and the thin copper film 5 on the main surface side and the thin copper film 5 on the back surface side are electrically coupled by the copper film 5A inside the through-hole 7 (see FIG. 7). Subsequently, after attaching a photoresist film 8 formed of dry film to both the main and back surfaces of the core material 6 (see FIG. 8), the photoresist film 8 is patterned by photolithography (see FIG. 9). Subsequently, the thin copper film 5 is patterned by etching the thin copper film 5 on both surfaces of the core material 6 using the photoresist film 8 as a mask. A first level wiring layer including wiring 9 can be formed on both surfaces of the core material 6 through the processes up to here (see FIG. 10). In addition, the wiring layer on both surfaces of the core material 6 can have a structure electrically coupled via the copper film 5A in the through-hole 7.

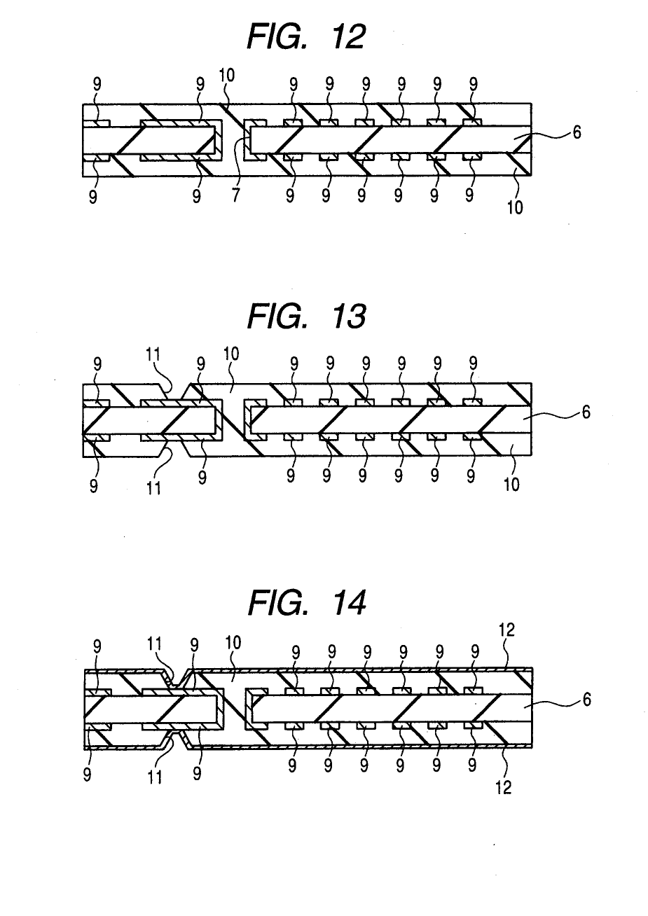

Next, an insulating layer 10 is deposited on both surfaces of the core material 6 after removing the photoresist film 8 (see FIG. 11). In addition, the through-hole 7 is buried by this insulating layer 10 (see FIG. 12). Similarly with the core material 6, glass epoxy resin, BT resin, aramid nonwoven fabric, or the like may be exemplified as the material of the insulating layer 10.

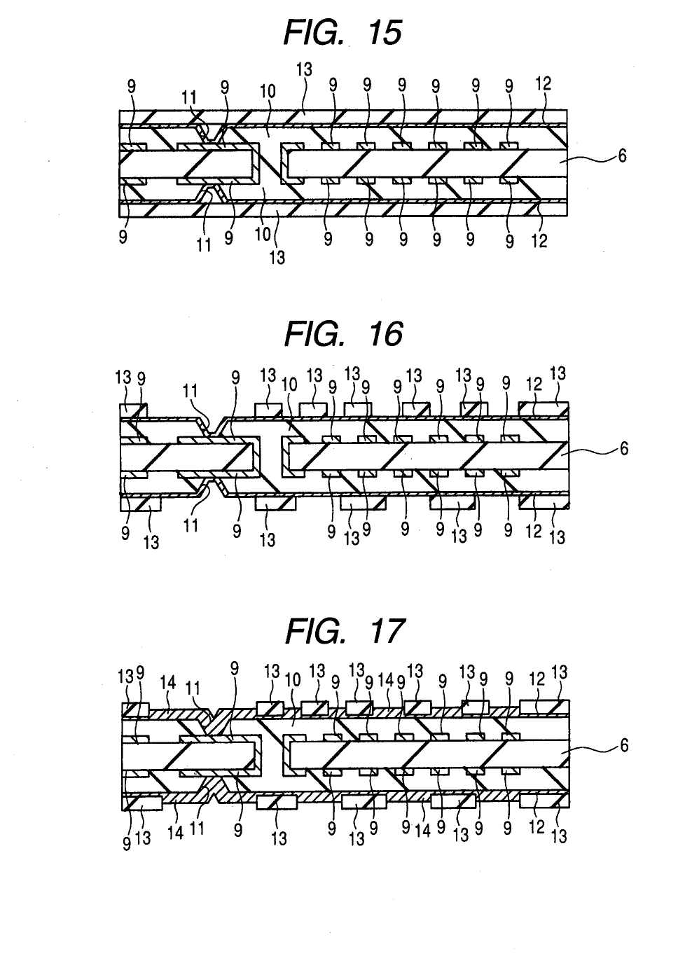

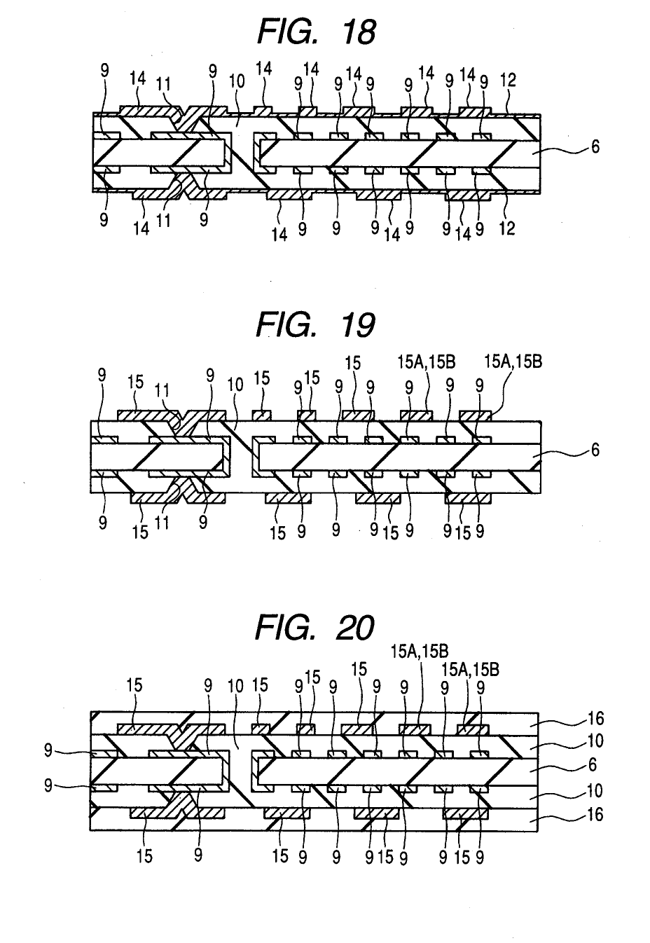

Next, an opening 11 that reaches a part of the wiring 9 is formed in the insulating layer 10 of both surfaces of the core material 6 by laser processing (see FIG. 13). Subsequently, a copper film 12 is formed on both surfaces of the core material 6 by nonelectrolytic plating (see FIG. 14). In this occasion, the copper film 12 is also formed in the opening 11, and the copper film 12 and the wiring 9 are coupled at the bottom of the opening 11. Subsequently, after attaching a photoresist film 13 formed of a dry film to both the main and back surfaces of the core material 6 (see FIG. 15), the photoresist film 13 is patterned by photolithography (see FIG. 16). Subsequently, a copper film 14 is selectively grown over the copper film 12 by electrolytic plating using the remaining photoresist film 13 as a mask and the copper film 12 as a seed layer (see FIG. 17). Subsequently, after peeling the photoresist film 13 (see FIG. 18), the copper film 12 located under the photoresist film 13 before the peeling is removed by nonelectrolytic etching, and a wiring 15 formed. A second level wiring layer including the wiring 15 can be formed on both surfaces of the core material 6 through the processes up to here (see FIG. 19). A part of the wiring 15 has a structure coupled to the wiring 9 at the bottom of the opening 11.

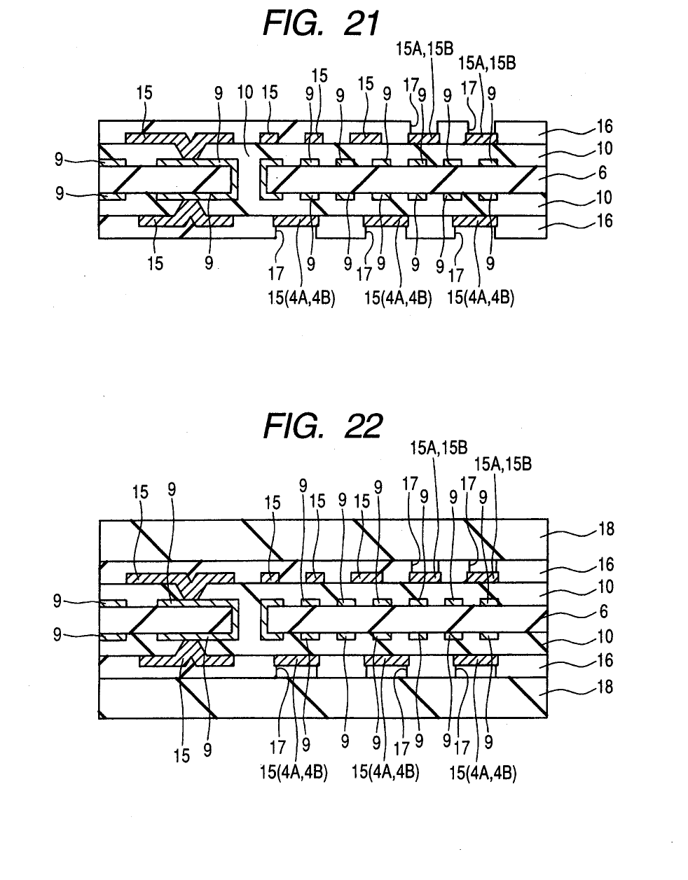

Next, a solder resist 16 is printed on both surfaces of the core material 6 (see FIG. 20), the solder resist 16 is then patterned by photolithography to form an opening 17 that reached a part of the wiring 15 in the solder resist 16 (see FIG. 21). On the main surface side of the core material 6, a part of the wiring 15 exposed at the bottom of opening 17 functions as the electrode pad 3C (not shown in FIG. 21) of the motherboard 1 for mounting chips mentioned above. Additionally, on the back surface side of the core material 6, the wiring 15 exposed at the bottom of opening 17 functions as the electrode pad 4A of the motherboard 1 or the electrode pad 4B of the motherboard 2 mentioned above.

Next, the above-mentioned guide holes 1A and 2A that penetrate through the core material 6 are formed by drilling (see FIGS. 1 to 4).

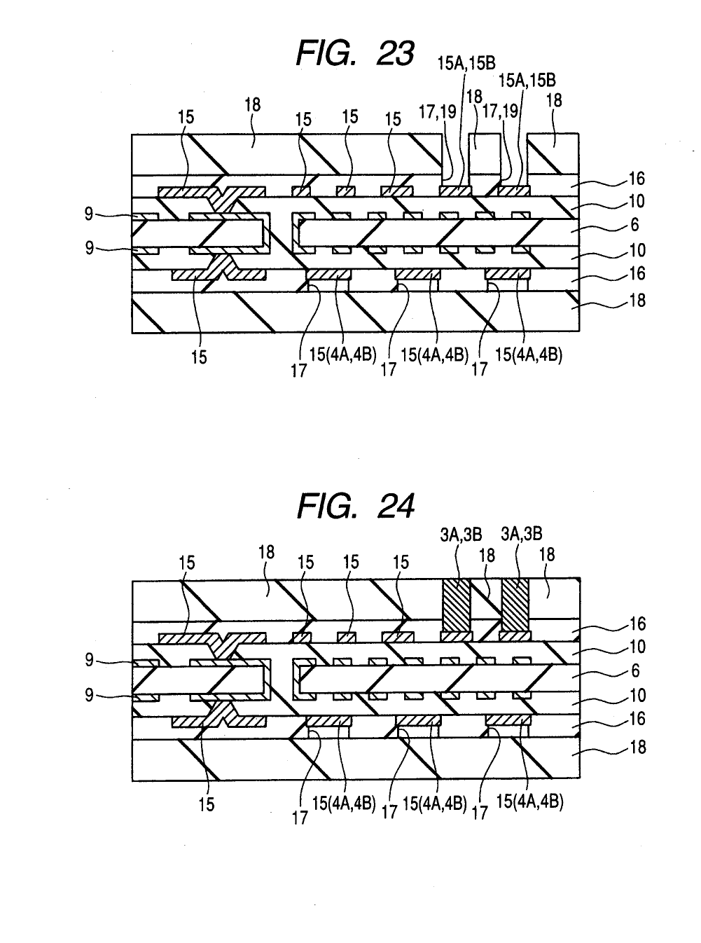

Next, after attaching a photoresist film 18 formed of a dry film to both the main and back surfaces of the core material 6 (see FIG. 22), the photoresist film 18 on the main surface side is patterned by photolithography, and an opening 19 is formed in the photoresist film 18 over the opening 17 of the main surface side (see FIG. 23). Subsequently, the conductive members 3A and 3B described referring to FIGS. 1 and 4 are formed by selectively growing a copper film over the wiring 15 by plating using the remaining photoresist film 18 as a mask and the wiring 15 under the openings 17 and 19 as a seed layer (see FIG. 24). Subsequently, the motherboards 1 and 2 are manufactured by peeling the photoresist film 18 (see FIG. 25).

Here, in this embodiment, when a chip to be mounted on the wiring substrate 1C is joined (flip chip coupled) to the wiring substrate 1C using a bump electrode, it is arranged in the motherboards 1 and 2 such that the height H1 of the conductive members 3A and 3B from the surface of the solder resist 16 becomes lower than the height of the semiconductor chip 22 when mounted on the wiring substrate 1C (height from the surface of the solder resist 16 to the back surface of the semiconductor chip 22), and the sum of the height H1 of conductive member 3A and the height H1 of the conductive member 3B becomes larger than the height of the semiconductor chip 22. For example, if the height of the semiconductor chip 22 is about 80 μm, the height of the conductive members 3A and 3B is set to be about 50 μm.

The motherboards 1 and 2 of this embodiment as described above can be manufactured also by other processes. The processes will be described referring to FIGS. 26 to 33.

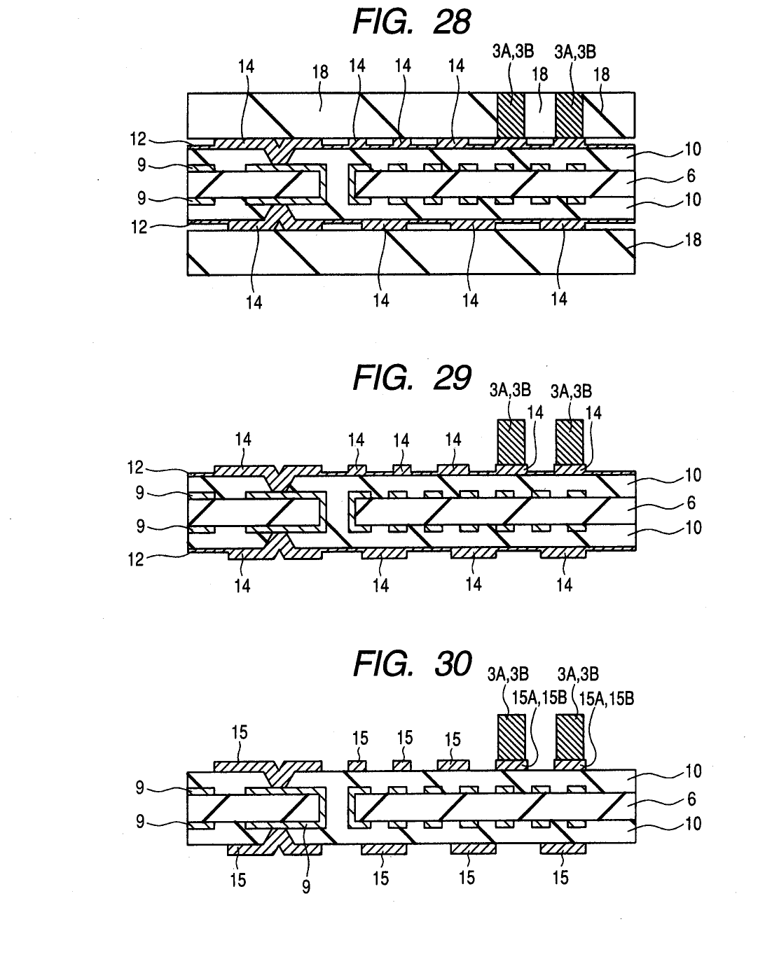

After the processes described referring to FIGS. 5 to 18, subsequent to attaching the photoresist film 18 formed of a dry film to both the main surface and back surfaces of the core material 6 (see FIG. 26), the photoresist film 18 on the main surface, side is patterned by photolithography to form the opening 19 that selectively reaches the copper film 14 in the photoresist film 18 over the copper film 14 on the main surface side (see FIG. 27). Subsequently, the conductive members 3A and 3B described referring to FIGS. 1 and 4 are formed by selectively growing a copper film over the copper film 14 by plating using the remaining photoresist film 18 as a mask and the copper film 14 under the opening 19 as the seed layer (see FIG. 28).

Next, after peeling the photoresist film 18 (see FIG. 29), the copper film 12 is etched by nonelectrolytic etching method and the wiring 15 is formed from the remaining copper film 12 and the copper film 14. Here, a part of the wiring 15 functions as the electrode pad 15A or the electrode pad 15B mentioned above. A second level wiring layer including the wiring 15 can be formed on both surfaces of the core material 6 through the processes up to here (see FIG. 30). A part of the wiring 15 has the structure coupled to the wiring 9.

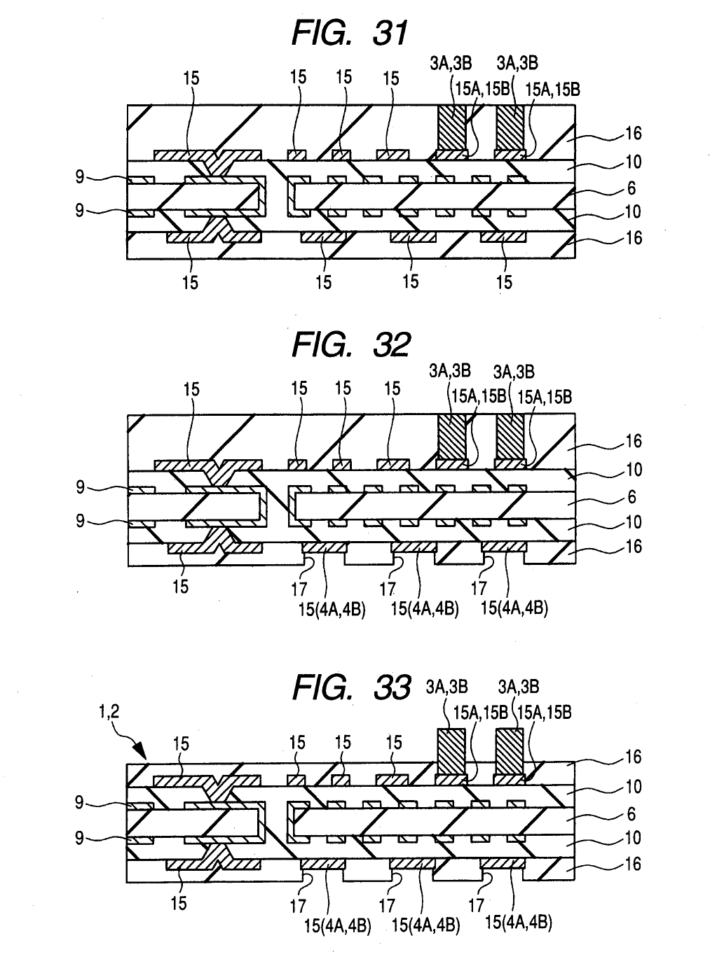

Next, the solder resist 16 is printed on both surfaces of the core material 6 (see FIG. 31). In this occasion, the thickness of the solder resist 16 on the main surface side of the core material 6 is made thicker than the height of the conductive members 3A and 3B. Subsequently, the solder resist 16 is patterned by photolithography to form the opening 17 that reaches a part of the wiring 15 in the solder resist 16 (see FIG. 32). On the main surface side of the core material 6, a part of the wiring 15 exposed at the bottom of opening 17 functions as the electrode pad 3C (not shown in FIG. 32) of the motherboard 1 for mounting semiconductor chips mentioned above. Additionally, on the back surface side of the core material 6, the wiring 15 exposed at the bottom of the opening 17 functions as the electrode pad 4A of the motherboard 1 or the electrode pad 4B of the motherboard 2 mentioned above.

Next, the solder resist 16 on the main surface side of the core material 6 is thinned by blasting, and whereby the conductive members 3A and 3B are caused to project from the surface of the solder resist 16. Subsequently, the above-mentioned guide holes 1A and 2A (see FIGS. 1 to 4) that penetrate through the core material 6 are formed by drilling to manufacture the motherboards 1 and 2 (see FIG. 33). In this occasion, it is arranged such that when a chip to be mounted on the base substrate is joined (flip chip coupled) to the base substrate using a bump electrode, the height of projection of the conductive members 3A and 3B from the surface of the solder resist 16 becomes lower than the height of the chip when mounted on the base substrate (height from the surface of the solder resist 16 to the back surface of the chip), and sum of the height of conductive member 3A and the height of conductive member 3B becomes higher than the height of the chip. For example, if the height of the chip is about 80 μm, the height of the conductive members 3A and 3B is set to be about 50 μm.

With regard to the motherboards 1 and 2 manufactured by the processes described above, since a signal line from the upper wiring substrate 2C is guided to the lower wiring substrate 1C in a POP semiconductor device, the wiring substrate 1C has more internal wiring layers than the wiring substrate 2C such that the number of layers is four for the wiring substrate 1C whereas it is two for the wiring substrate 2C. Therefore, a structure having more layers may be formed by skipping the process of forming the insulating layer 10 and the wiring 15 when manufacturing the motherboard 2 to be the wiring substrate 2C, or repeating the process of forming the insulating layer 10 and the wiring 15 when manufacturing the motherboard 1 to be the wiring substrate 1C.

Next, a process of manufacturing a POP semiconductor device of this embodiment using the motherboards 1 and 2 manufactured through the processes described above will be described, referring to FIGS. 34 to 49.

First, the motherboard 1 is prepared, and a metal film (conductive film) 21 is formed on the surface of the conductive member (post) 3A formed over the electrode pad 15A so as to project from the solder resist 16 (see FIG. 25 or 33). As the metal film 21, a solder plating film or a solder plating film laminated over a plating film including gold or Ni—Au alloy can be exemplified. In a subsequent process, the conductive member 3A is joined to the conductive member 3B formed on the lower surface of wiring substrate (sub-substrate) 2C, where strength of joint with the conductive member 3B can be enhanced because the metal film 21 is formed on the surface thereof. The problem in a subsequent mold process that the joint of the conductive member 3A formed in the wiring substrate 1C and the conductive member 3B formed in the wiring substrate 2C is fractured by the injection pressure of the resin provided between the lower wiring substrate 1C and the upper wiring substrate 2C can thus be avoided. In addition, when Ni—Au alloy is included in the metal film 21, oxidization of the surface of the conductive member 3A can be prevented. Although not shown, similar metal film 21 is also formed on the surface of the electrode pad 3C.

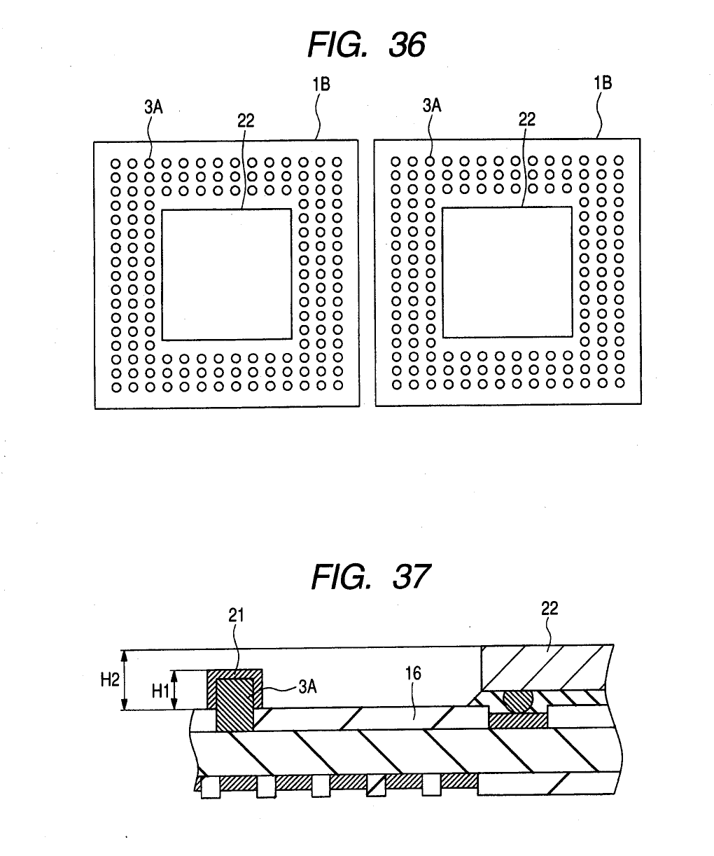

Next, the semiconductor chip 22 is mounted in a region to be each wiring substrate 1C in the main surface of the motherboard 1 (see FIG. 35). Here, FIG. 36 is an enlarged plan view illustrating a region 1B to be two adjacent wiring substrates 1C. In the examples shown in FIGS. 35 and 36, the semiconductor chip 22 is mounted in a region supposed to be each wiring substrate 1C by forming a bump electrode (projection electrode) 23 over a bonding pad (not shown) formed on the surface thereof, and joining the bump electrode with the electrode pad 3C. In this occasion, the semiconductor chip 22 is mounted with the surface side having elements formed thereon facing the motherboard 1.

As has been discussed in the description of the process of manufacturing the motherboards 1 and 2, the height of projection H1 of the conductive member 3A from the surface of the solder resist 16 is lower than the height (height from the surface of the solder resist 16 to the back surface of the semiconductor chip 22) H2 of the semiconductor chip 22 mounted on the region to be the base substrate, as shown in FIG. 37.

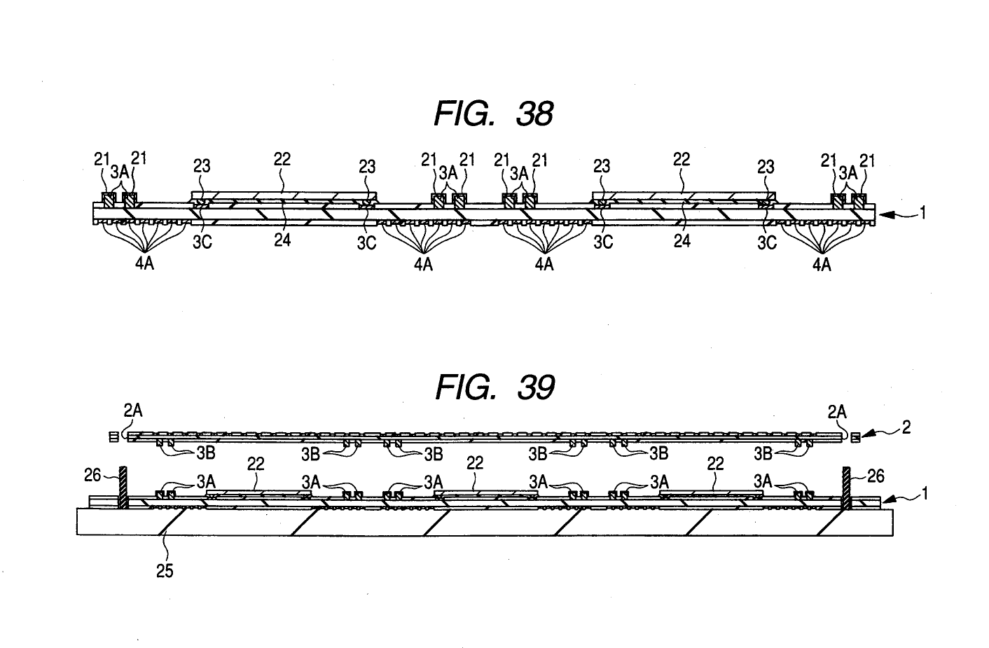

Next, after coating an underfill resin 24 between the semiconductor chip 22 and the motherboard 1 (see FIG. 38), the motherboard 1 is mounted on a stage 25 for thermocompression bonding (see FIG. 39). In this occasion, the back surface side of the mounted motherboard 1 faces the stage 25, and positioning of the motherboard 1 over the stage 25 can be performed by inserting a guide pin 26 provided to the stage 25 through the guide hole 1A (see FIGS. 1 and 2) of the motherboard 1. Subsequently the motherboard 2 is prepared (see FIG. 39).

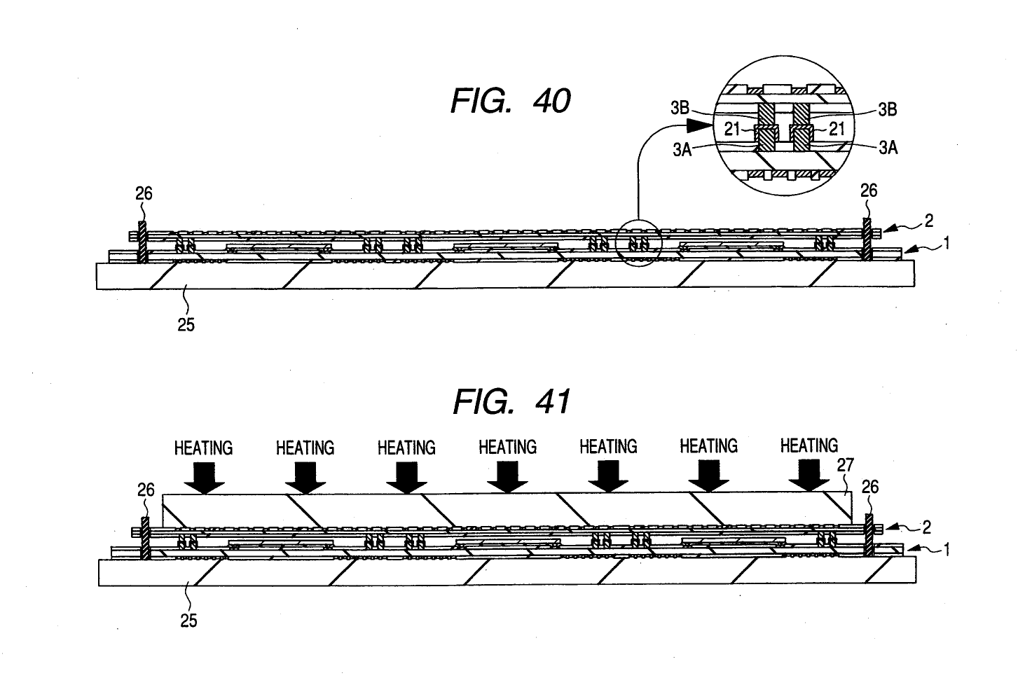

Next, the motherboard 2 is mounted on the stage 25 (see FIG. 40). In this occasion, the back surface side of the motherboard 2 having the conductive member 3B formed thereon faces the motherboard 1, and the position of the motherboard 2 over the stage 25 is determined by inserting the guide pin 26 through the guide hole 2A of the motherboard 2, so that corresponding ones of the conductive members 3A and the conductive members 3B face and contact each other on a one to one basis. FIG. 40 also illustrates an enlarged cross-sectional view of the contact portion of the conductive member 3A (metal film 21) and the conductive member 3B. In addition, when the positions of the motherboards 1 and 2 over the stage 25 are determined, the regions to be the wiring substrates 1C sectioned in the motherboard 1 face, on a one to one basis, the corresponding regions to be the wiring substrates 2C sectioned in the motherboard 2.

Next, the conductive member 3A and the conductive member 3B are thermocompression-bonded (joined) by applying heat and pressure to the motherboard 2 from the back surface side using a heating tool 27, and they are electrically coupled (see FIG. 41). In this occasion, since the metal film 21 having a low resistance is formed on the surface of the conductive member 3A, the metal film 21 melts during the thermocompression bonding, and whereby the conductive member 3A and the conductive member 3B are joined via the metal film 21. Thus it becomes possible to reduce the contact resistance between the conductive member 3A and the conductive member 3B.

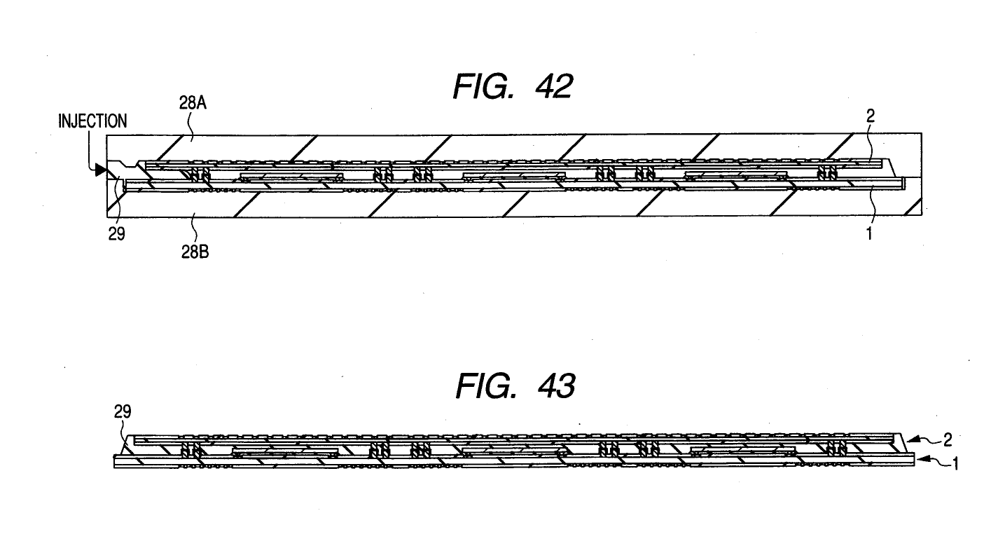

Next, mold resin 29 is injected between the motherboard 1 and the motherboard 2 using mold dies 28A and 28B to form a sealing body for resin sealing between the motherboard 1 and the motherboard 2 (see FIG. 42). In this occasion, since the conductive members 3A and 3B are formed so as to be spaced apart from each other, as shown in FIGS. 1 and 4, the mold resin (resin) 29 provided between the motherboard 1 and the motherboard 2 is provided through between the conductive members 3A and 3B. Subsequently, the resin-sealed motherboards 1 and 2 are taken out from the mold dies 28A and 28B, and formed by removing the protruding mold resin 29 (see FIG. 43).

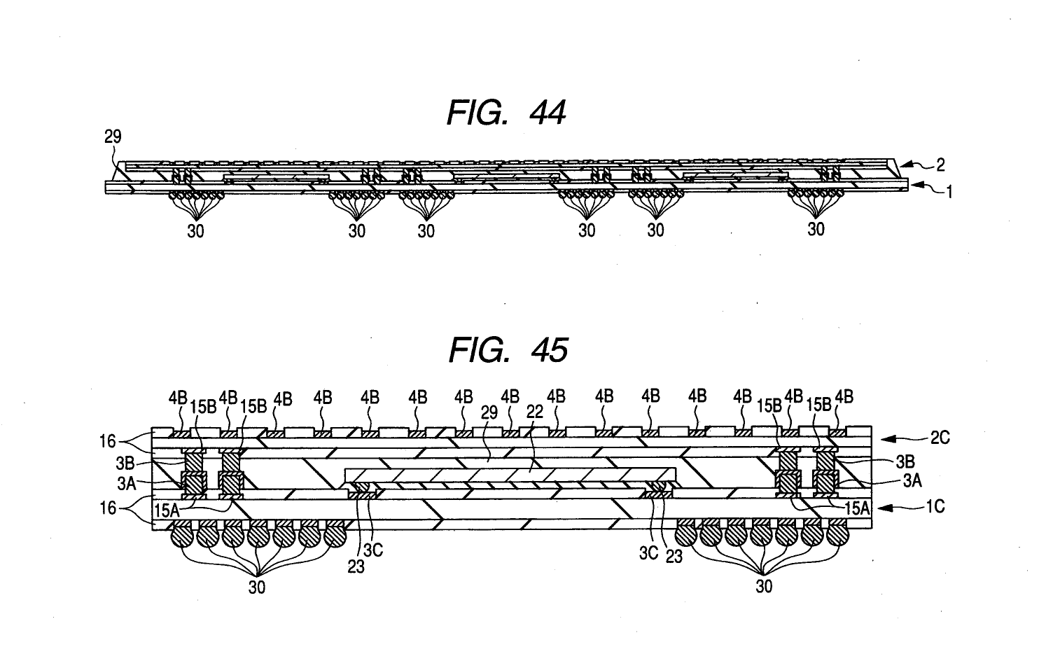

Next, a solder ball is placed on each electrode pad 4A of the motherboard 1. The solder ball is joined with the electrode pad 4A by reflow processing to form a bump electrode (external terminal) 30 (see FIG. 44).

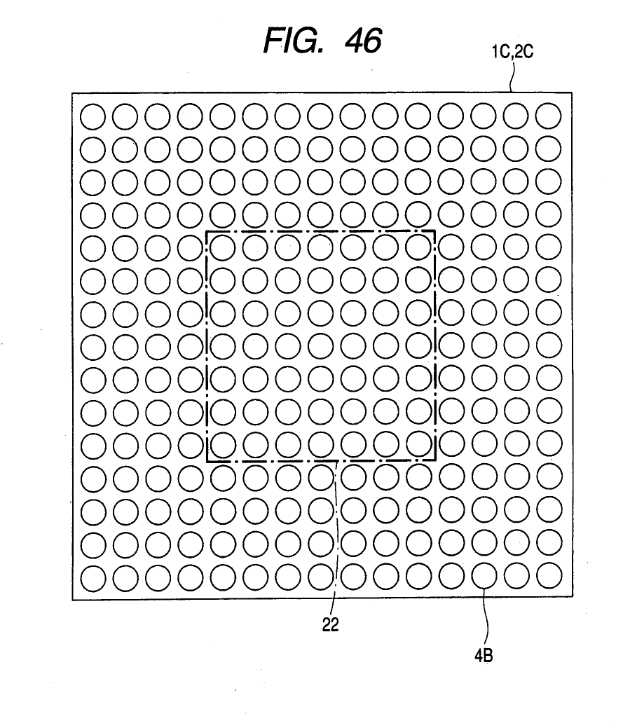

Next, the motherboards 1 and 2 are cut along the planar outline of the regions to be the wiring substrate 1C and the wiring substrate 2C into individual sets of the wiring substrate 1C and the wiring substrate 2C (see FIG. 45). FIG. 46 is a plan view of a set of the wiring substrate 1C and the wiring substrate 2C after divided into the individual set. As shown in FIG. 46, the planar dimensions of the wiring substrate 1C and the wiring substrate 2C are identical because the motherboards 1 and 2 are cut together in this embodiment. Additionally, in this embodiment, the electrode pad 4B electrically coupled to the conductive member 3B is placed also at a position planarly overlapping the semiconductor chip 22. In other words, the wiring substrate 2C can also mount chips or chip components at a position planarly overlapping the lower semiconductor chip 22. Accordingly, the number of electrode pads 4B to be placed on the wiring substrate 2C can be increased without increasing the external size of the wiring substrate 1C and the wiring substrate 2C. In addition, because the external size of the wiring substrate 1C and the wiring substrate 2C can be reduced if the numbers of electrode pads 4B are the same, the semiconductor device of this embodiment can also be downsized.

Next, the semiconductor member 32 having a bump electrode formed thereon is prepared as an external coupling electrode. Subsequently, the semiconductor member 32 is mounted and electrically coupled to the wiring substrate 2C by coupling the bump electrode 31 to the electrode pad 4B of the wiring substrate 2C, and whereby the semiconductor device (semiconductor system) SDS of this embodiment is manufactured. FIG. 48 is a plan view at the time point when the semiconductor member 32 is mounted, on the wiring substrate 2C. According to this embodiment, the upper semiconductor member 32 can also be placed in a region planarly overlapping the lower semiconductor chip 22. Although FIG. 48 illustrates a case where the planar dimension of the semiconductor member 32 is approximately same as that of the wiring substrate 1C and the wiring substrate 2C, the planar dimension of the semiconductor member 32 may be smaller.

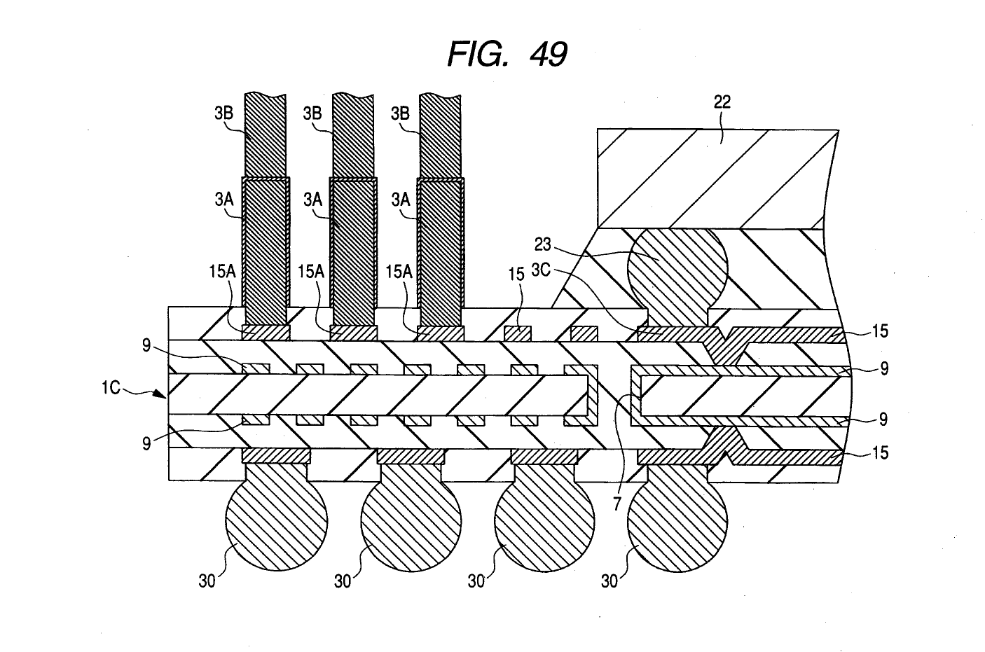

FIG. 49 is a cross-sectional view illustrating the main parts of the POP semiconductor device of this embodiment, and FIG. 50 is an exemplary system block diagram when the POP semiconductor device of this embodiment is mounted on an externally installed substrate such as a motherboard.

It can be exemplified that the semiconductor chip 22 mounted on the lower wiring substrate 1C is an SOC (System On Chip) chip which performs logic processing such as image processing, and the semiconductor member 32 mounted on the upper wiring substrate 2C is a memory chip which is used as a work RAM for the logic processing performed by the lower semiconductor chip 22. Signals are exchanged between the semiconductor chip 22 and the semiconductor member 32 via the bump electrode 23, the wirings 9 and 15, the conductive members 3A and 3B, and the bump electrode 30. Signals are exchanged between the semiconductor chip 22 and external LSI 33 via the bump electrode 23, the wirings 9 and 15, and the bump electrode 30. The power source potential (VDD) and the reference potential (GND) are supplied to the semiconductor chip 22 via the bump electrodes 23 and 30 and the wirings 9 and 15, whereas the power source potential (VDD) and the reference potential (GND) are supplied to the semiconductor member 32 via the bump electrodes 23 and 30, the conductive members 3A and 3B, the electrode pad 4B, and the wirings 9 and 15, without going through the semiconductor chip 22.

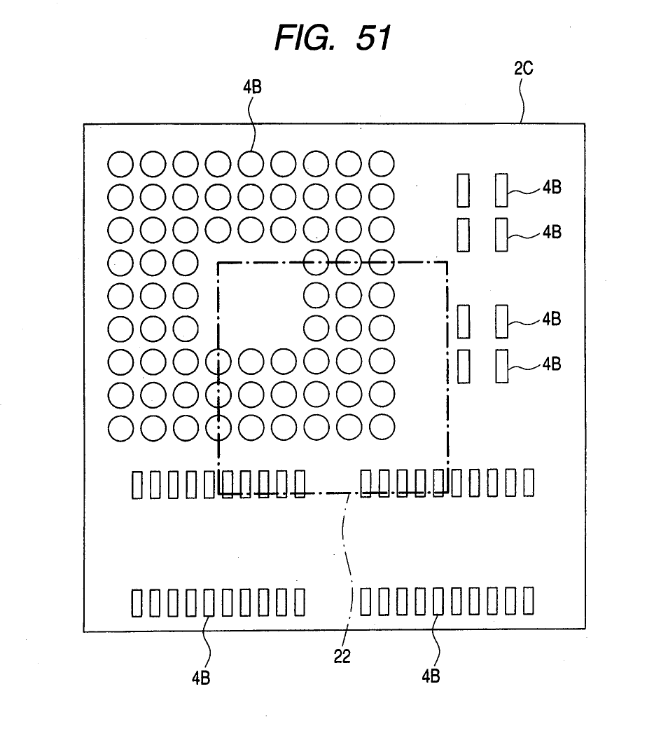

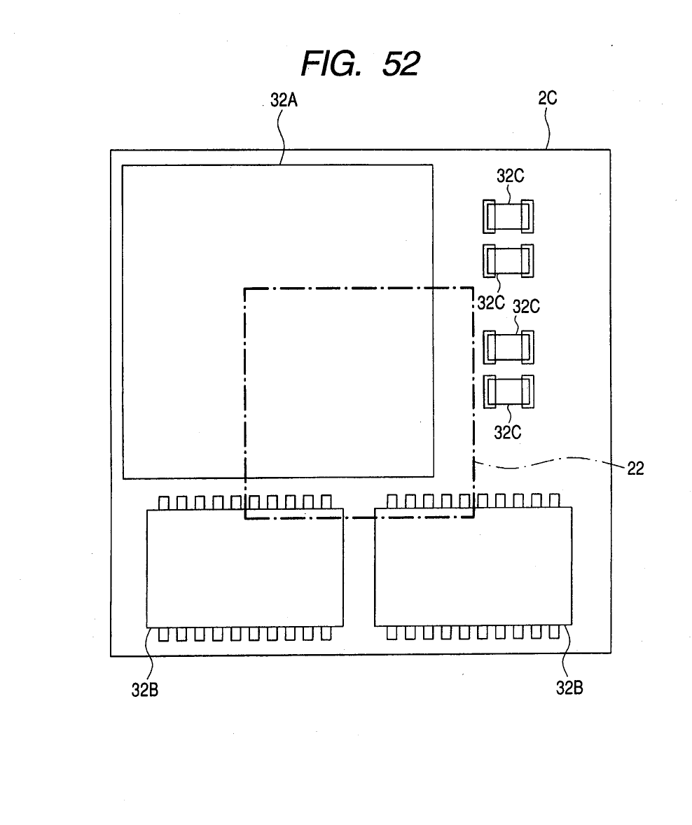

In addition, it is also possible to mount a plurality of semiconductor chips (microcomputer chips, memory chips, etc.) or chip components (resistors, capacitors, inductors, etc.) on the wiring substrate 2C. FIG. 51 is a plan view of the wiring substrate 2C which is made capable of mounting a plurality of semiconductor chips and chip components. The pad electrode 4B provided on the wiring substrate 2C is formed to have a planar shape that matches the semiconductor chips and chip components to be mounted. Even in such a case, the pad electrode 4B can be placed at a position where it overlaps the lower semiconductor chip 22. FIG. 52 is a plan view in which the semiconductor chips 32A and 32B, and the chip components 32C are mounted on the wiring substrate 2C. According to this embodiment, the upper semiconductor chips 32A and 32B, and the chip components 32C can be placed in regions where they planarly overlap the lower semiconductor chip 22. In other words, it becomes possible to significantly expand the combination of the semiconductor chips 22, 32, 32A and 32B, and the chip components 32C on the upper and the lower layers, according to this embodiment.

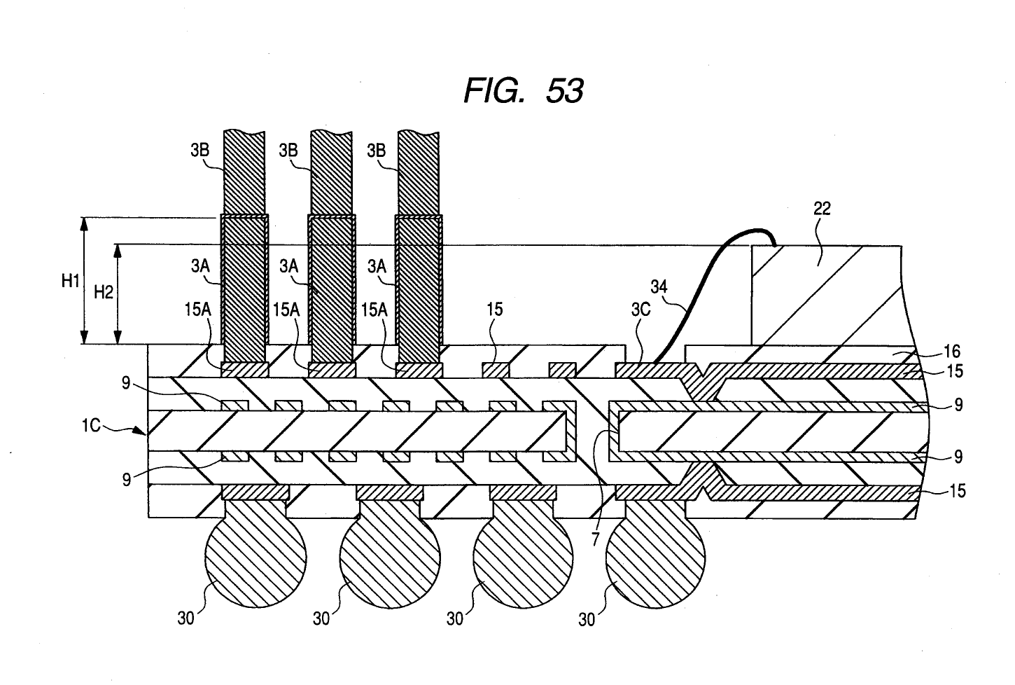

In this embodiment, although a case has been described where the semiconductor chip 22 to be mounted on the wiring substrate 1C is installed via the bump electrode 23, it may be installed by a bonding wire 34 as shown in FIG. 53. In this case, although the electrode pad 3C of the wiring substrate (base substrate) 1C electrically coupled to the bump electrode 23 formed over an electrode pad (not shown) of the semiconductor chip 22 is formed in a region planary overlapping the semiconductor chip 22 in the main surface of the wiring substrate (base substrate) 1C of the above-mentioned embodiment, the electrode pad 3C is formed around the region on the wiring substrate (base substrate) 1C where the semiconductor chip 22 is mounted, as shown in FIG. 53. Because a loop of the bonding wire 34 is formed over the semiconductor chip 22 when such a bonding wire 34 is used, it is preferred that the projection height H1 of the conductive member 3A from the surface of the solder resist 16 of the wiring substrate 1C is made higher than the thickness H2 of the semiconductor chip 22 (height from the surface of the solder resist 16 to the surface of the semiconductor chip 22).

According to the above-mentioned embodiment, a structure (see FIG. 47) is provided where the mold resin 29 is provided between the semiconductor chip 22 (the back surface when installed by the bump electrode 23, and the main surface when installed by the bonding wire 34) mounted on the wiring substrate 1C and the wiring substrate 2C. Bending of the wiring substrate 2C when a POP semiconductor device of this embodiment is installed can thus be avoided. In other words, yield of semiconductor devices of this embodiment can be increased, with improved reliability as well.

In addition, according to this embodiment, the conductive member 3A and the conductive member 3B can be easily aligned and joined because the motherboards 1 and 2 are aligned using the guide holes 1A and 2A preliminarily formed in the motherboards 1 and 2 to provide thermocompression bonding of the corresponding conductive members 3A and 3B respectively (see FIGS. 39 to 41).

According to this embodiment, additionally, the conductive member 3A and the conductive member 3B are coupled via a metal film 21 of a low resistance, and whereby contact resistance between the conductive member 3A and the conductive member 3B can be reduced. Therefore it becomes possible to cope with the increased operation speed of the semiconductor device of this embodiment.

Although specific descriptions have been provided above based on embodiments of the invention made by the inventors, it is needless to say that the present invention is not limited to the above-mentioned embodiments and a variety of modifications are possible without deviating from its spirit.

For example, although a case has been described in the above-mentioned embodiment where a post-shaped conductive member is also formed during the manufacturing process of the motherboard 1, the post-shaped conductive member may be formed, after manufacturing the motherboard 1, in the manufactured motherboard 1.

In addition, although a case has been described in the above-mentioned embodiments where metal film 21 is formed on the surface of the conductive member 3A formed on the base wiring substrate 1C, the metal film 21 may be formed on the surface of the conductive member 3B formed on the lower surface of the auxiliary wiring substrate 2C. Of course the metal film 21 may be formed on each of the surfaces of the conductive members 3A and 3B. Accordingly, not only the joining strength of the conductive members 3A and 3B can be increased but also electrical resistance can be reduced and delay of signal input and output in the semiconductor system can be avoided because oxidation on the surface of each of the conductive members 3A and 3B can be suppressed. In other words, speed of the semiconductor device (semiconductor system) can be further increased.

In addition, although processes up to mounting the semiconductor member 32 over the wiring substrate (sub-substrate) 2C have been described in the above-mentioned embodiment with the semiconductor device described as a situation where the semiconductor member 32 has been mounted thereon, a structure such as shown in FIG. 45 which is obtained by forming the bump electrode 30 on the lower surface of the wiring substrate (base substrate) 1C and cutting the wiring substrates 1C and 2C, and the sealing body 29 may be employed as a completed semiconductor device. In this case, the semiconductor system to be built can be varied according to the function of the applied electronic device as appropriate because the semiconductor device is managed or shipped in a state without the semiconductor member 32 being mounted thereon.

The method of manufacturing a semiconductor device and the semiconductor device according to the present invention can be applied to a MCM semiconductor device and the process of manufacturing the same.

What is claimed is:

1. A method of manufacturing a semiconductor device comprising the steps of:
(a) providing a first substrate having a first main surface, a first electrode pad formed on the first main surface, a second electrode pad placed closer to the periphery of the first main surface than the first electrode pad, a first conductive member formed on the second electrode pad, a conductive film formed on the surface of the first conductive member, a first back surface opposite to the first main surface, and a third electrode pad formed on the first back surface;
(b) mounting a semiconductor chip having a front surface, a bonding pad formed on the front surface, and a back surface opposite to the front surface on the first main surface of the first substrate;
(c) electrically coupling the bonding pad of the semiconductor chip and the first electrode pad of the first substrate via a second conductive member;
(d) disposing a second substrate having a second main surface, a fourth electrode pad formed on the second main surface, a second back surface opposite to the second main surface, a fifth electrode pad formed on the second back surface, and a third conductive member formed on the fifth electrode pad on the first substrate such that the second back surface of the second substrate faces the first main surface of the first substrate;
(e) after the step (d), electrically coupling the third conductive member to the first conductive member via the conductive film;
(f) after the step (e), supplying resin between the first substrate and the second substrate to seal the semiconductor chip and the joint of the first conductive member and the third conductive member; and
(g) after the step (f), forming an external terminal at the third electrode pad of the first substrate.

2. The method of manufacturing a semiconductor device according to claim 1,
wherein the conductive film has a higher melting point than the external terminal.

3. The method of manufacturing a semiconductor device according to claim 1,
wherein the semiconductor chip has a projection electrode coupled to the bonding pad; in the step (b), the semiconductor chip is mounted on the first main surface of the first substrate so that the surface of the semiconductor chip faces the first main surface of the first substrate; and, in the step (c), the projection electrode of the semiconductor chip is coupled to the first electrode pad of the first substrate, and the height of the semiconductor chip mounted on the first main surface of the first substrate is higher than the height of the first conductive member.

4. The method of manufacturing a semiconductor device according to claim 1,
wherein in the step (b), the semiconductor chip is mounted on the first main surface of the first substrate so that the back surface of the semiconductor chip faces the first main surface of the first substrate; and in the step (c), the bonding pad of the semiconductor chip and the first electrode pad of the first substrate are electrically coupled to each other via a bonding wire, and the thickness of the semiconductor chip is smaller than the height of the first conductive member.

5. The method of manufacturing a semiconductor device according to claim 1,
wherein the step (f) includes a step of forming a sealing body containing the resin between the semiconductor chip and the second back surface of the second substrate.

6. The method of manufacturing a semiconductor device according to claim 1,
wherein after the step (d), the fourth electrode pad of the second substrate is formed in a region planarly overlapping the semiconductor chip mounted on the first substrate.

7. The method of manufacturing a semiconductor device according to claim 1,
wherein the first conductive member and the third conductive member are formed by plating.

8. The method of manufacturing a semiconductor device according to claim 1, wherein wiring layers are formed inside the first substrate and the second substrate respectively, and the
wiring layer formed on the first substrate has more layers than that of the second substrate.

9. The method of manufacturing a semiconductor device according to claim 1,
wherein the first substrate and the second substrate have the same planar dimension.

10. A semiconductor device comprising:
a first substrate having a first main surface, a first electrode pad formed on the first main surface, a second electrode pad placed closer to the periphery of the first main surface than the first electrode pad, a first conductive member formed on the second electrode pad, a first back surface opposite to the first main surface, and a third electrode pad formed on the first back surface;
a semiconductor chip having a front surface, a bonding pad formed on the front surface, and a back surface opposite to the front surface, and mounted on the first main surface of the first substrate;
a second conductive member electrically coupling the bonding pad of the semiconductor chip and the first electrode pad of the first substrate;
a second substrate having a second main surface, a fourth electrode pad formed on the second main surface, a second back surface opposite to the second main surface, a fifth electrode pad formed on the second back surface, and a third conductive member formed on the fifth electrode pad, and disposed on the first substrate such that the second back surface faces the first main surface of the first substrate;
a conductive film electrically coupling the first conductive member and the third conductive member;
resin formed between the first substrate and the second substrate so as to seal the semiconductor chip and the joint of the first conductive member and the third conductive member; and
an external terminal formed on the third electrode pad of the first substrate,
wherein the resin is formed between the semiconductor chip and the second back surface of the second substrate.

11. The semiconductor device according to claim 10,
wherein the semiconductor chip has a projection electrode coupled to the bonding pad; the semiconductor chip is mounted on the first main surface of the first substrate so that the surface of the semiconductor chip faces the first main surface of the first substrate; and the projection electrode of the semiconductor chip is coupled to the first electrode pad of the first substrate, and the height of the semiconductor chip mounted on the first main surface of the first substrate is higher than the height of the first conductive member.

12. The semiconductor device according to claim 10,
wherein the semiconductor chip is mounted on the first main surface of the first substrate so that the back surface of the semiconductor chip faces the first main surface of the first substrate; and the bonding pad of the semiconductor chip and the first electrode pad of the first substrate are electrically coupled via a bonding wire, and the thickness of the semiconductor chip is smaller than the height of the first conductive member.

13. The semiconductor device according, to claim 10,
wherein the fourth electrode pad of the second substrate is formed in a region planarly overlapping the semiconductor chip mounted on the first substrate.

14. The semiconductor device according to claim 10,
wherein wiring layers are formed inside the first substrate and the second substrate respectively, and the wiring layer formed on the first substrate has more layers than that of the second substrate.

15. The semiconductor device according to claim 10,
wherein the first substrate and the second substrate have the same planar dimension.

16. The semiconductor device according to claim 10,
wherein the second main surface of the second substrate has mounted thereon one or more of at least one of another semiconductor chip of the same or a different type as that of the semiconductor chip, and a chip component.
